(19) United States
(12) Patent Application Publication
(10) Pub. No.: US 2025/0280548 A1
(43) Pub. Date: Sep. 4, 2025

(54) CAPACITOR STRUCTURE AND METHOD FOR FABRICATING THE CAPACITOR

(71) Applicant: Taiwan Semiconductor Manufacturing Company, Ltd., Hsinchu (TW)

(72) Inventors: Yu-Cheng Tsai, Tainan City (TW); Jen-Cheng Liu, Hsin-Chu City (TW); Ming-Tsong Wang, Taipei City (TW)

(73) Assignee: Taiwan Semiconductor Manufacturing Company, Ltd., Hsinchu (TW)

(21) Appl. No.: 18/590,956

(22) Filed: Feb. 29, 2024

(51) Int. Cl. H01L 21/768; H01L 23/522

(52) U.S. Cl. CPC H10D 1/042; H01L 21/76816; H01L 23/5223; H10D 1/043; H10D 1/714; H10D 1/716

(57) ABSTRACT

A capacitor structure and a method for fabricating the capacitor are provided. The method includes forming a stack of a first electrode layer, a first dielectric layer, a second electrode layer, a second dielectric layer and a third electrode layer; forming a first spacer on the second dielectric layer and patterning the second dielectric layer and the second electrode layer by using the first spacer as a mask; forming a second spacer on the first dielectric layer and patterning the first dielectric layer and the first electrode layer by using the first spacer and the second spacer as a mask; and forming a first conductive layer on the first spacer and the second spacer to electrically connect the third electrode layer and the first electrode layer.

### BACKGROUND

Integrated chips are formed on semiconductor die including millions or billions of transistor devices. The transistor devices are configured to act as switches and/or to produce power gains so as to enable logical functionality for an integrated chip (e.g., form a processor configured to perform logic functions). Integrated chips also include passive devices, such as capacitors, resistors, inductors, varactors, etc. Therefore, the improved the capacitors and the improved process of fabricating the capacitors are desired as a development of a semiconductor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 32 illustrate the cross-sectional views of intermediate stages in the formation of a metal-insulator-metal (MIM) device in accordance with some embodiments.

FIG. 33 to FIG. 37 illustrate the cross-sectional views of intermediate stages in the formation of a MIM device in accordance with some embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure and a method for fabricating the capacitor are provided. At least one pair of self-aligned spacers are utilized in the fabrication method for forming the capacitor structure to decrease the number of photomasks used in patterning processes of material layers in the capacitor structure. Therefore, the fabrication costs of the capacitor structure can be lowered.

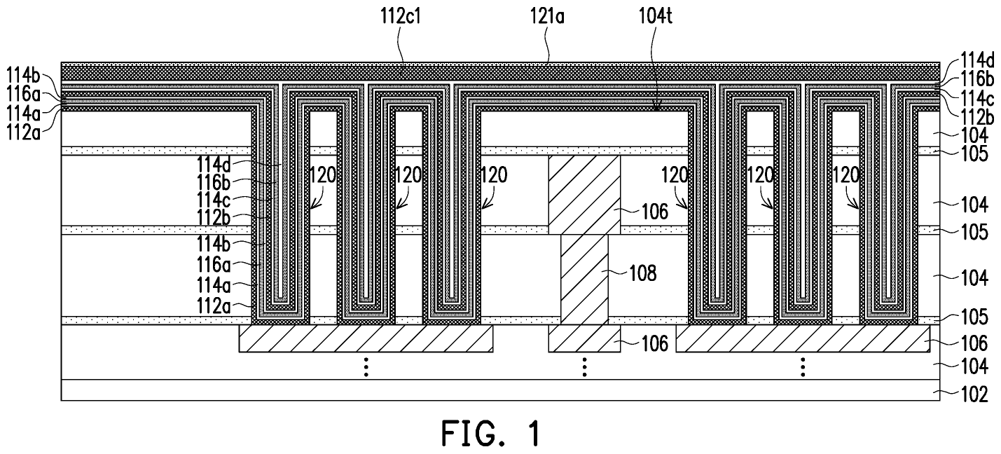

FIG. 1 to FIG. 32 illustrate the cross-sectional views of intermediate stages in the formation of a metal-insulator-metal (MIM) device in accordance with some embodiments.

Referring to FIG. 1, an interconnect structure including insulating layers 104, etch stop layers 105, interconnect wirings 106 and conductive vias 108 is formed over a substrate 102 (e.g., a semiconductor substrate). The interconnect wirings 106 and the conductive vias 108 are alternatively stacked over the substrate 102 and are embedded in the insulating layers 104 and the etch stop layers 105. The interconnect wirings 106 and the conductive vias 108 may be formed by, for example, CVD, PVD, ALD, sputtering, electrochemical plating, electroless plating, some other deposition process, or a combination of the foregoing. The insulating layers 104 and the etch stop layers 105 may be formed by, for example, chemical vapor deposition (CVD), physical vapor deposition (PVD), atomic layer deposition (ALD), some other process, or a combination of the foregoing. While not shown in FIG. 1, it will be appreciated that one or more semiconductor devices (e.g., transistors, MOSFETs, etc.), may be formed in the substrate 102 by complementary metal-oxide-semiconductor (CMOS) processes.

A plurality of trenches 120 is formed on the interconnect wirings 106 such that the interconnect wirings 106 are revealed. The trenches 120 pass through the insulating layers 104 and the etch stop layers 105, and reveal top surfaces of the interconnect wirings 106. The trenches 120 are formed in the insulating layers 104 and the etch stop layers 105. The trenches 120 extends from a top surface 104t of the insulating layer 104 to the top surfaces of the interconnect wirings 106. The trenches 120 are formed with substantially vertical sidewalls. In other embodiments, the trenches 120 are formed with inclined sidewalls. In some embodiments, at least one of the interconnect wirings 106 and at least one of the conductive vias 108 are disposed between two adjacent trenches 120.

A plurality of conformal electrode layers 112a, 116a, 112b, 116b and a plurality of conformal dielectric layers 114a-114d are formed in an alternating stack on the interconnect wirings 106 and lining the trenches 120, and extends over the top surface 104t of the insulating layer 104. The electrode layer 112c1 is formed on the dielectric layer 114d and laterally extends over the trenches 120 and the top surface 104t of the insulating layer 104. In some embodiments, as shown in FIG. 1, a first electrode layer 112a extends over the top surface 104t of the insulating layer 104 and lining the trenches 120. The first electrode layer 112a lands on and is electrically connected to the interconnect wirings 106. A first dielectric layer 114a conformally covers the first electrode layer 112a. A second electrode layer 116a conformally covers the first dielectric layer 114a. A second dielectric layer 114b conformally covers the second electrode layer 116a. A third electrode layer 112b conformally covers the second dielectric layer 114b. A third dielectric layer 114c conformally covers the third electrode layer 112b. A fourth electrode layer 116b conformally covers the third dielectric layer 114c. A fourth dielectric layer 114d conformally covers the fourth electrode layer 116b. A fifth electrode layer 112c1 covers the fourth dielectric layer 114d.

In some embodiments, the electrode layers 112a, 116a, 112b, 116b, 112c1 may be deposited by, for example, ALD, CVD, PVD, electrochemical plating, electroless plating, sputtering, some other deposition process, or a combination of the foregoing. The electrode layers 112a, 116a, 112b, 116b, 112c1 may be conductive and may be or include titanium (Ti), titanium nitride (TiN), tantalum (Ta), tantalum nitride (TaN), aluminum (Al), aluminum titanium (AlTi), some other conductive material, or a combination of the foregoing. In some embodiments, the electrode layers 112a, 116a, 112b, 116b, 112c1 are deposited with a thickness between approximately 10 angstroms (Å) and approximately 1000 Å.

The dielectric layers 114a-114d are formed between adjacent electrode layers of the electrode layers 112a, 116a, 112b, 116b, 112c1. The dielectric layers 114a-114d may be or include zirconium oxide (ZrO₂), aluminum oxide (Al₂O₃), hafnium oxide (HfO₂), hafnium aluminum oxide (HfAlO), tantalum oxide (Ta₂O₅), some other dielectric material, or any combination of the foregoing. In some embodiments, the dielectric layers 114a-114d is or includes a metal oxide (e.g., ZrO₂, Al₂O₃, HfO₂, HfAlO, Ta₂O₅, or the like) and/or is or includes a high-k dielectric material. The dielectric layers 114a-114d may be deposited or grown by ALD, CVD, PVD, thermal oxidation, some other deposition or growth process, or a combination of the foregoing. In some embodiments, the dielectric layers 114a-114d is formed with a thickness between about 10 Å and about 500 Å. In some embodiments, a number of the dielectric layer may be 1 or more, a number of the conductive may be 2 or more. The number of the dielectric layers and the number of the electrode layers are not limited thereto.

Then, an insulating layer 121a is formed on the fifth electrode layer 112c1. In some embodiments, the insulating layer 121a may be formed by one or more deposition processes (e.g., a PVD process, a CVD process, a PECVD process, or the like). In various embodiments, the insulating layer 121a may include silicon dioxide, silicon oxynitride, and/or the like.

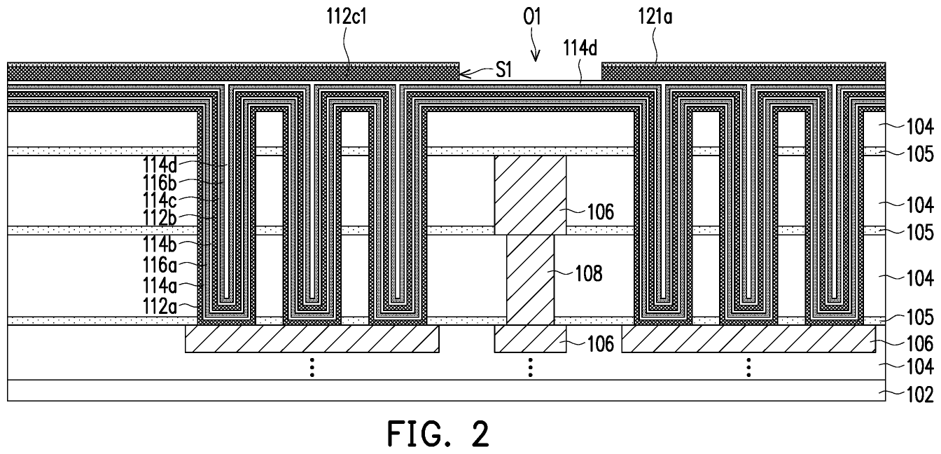

Referring to FIG. 2, the insulating layer 121a and the fifth electrode layer 112c1 are patterned by a photolithography process followed by an etch process, and a photomask is used in the photolithography process. In other words, a patterned photoresist layer (not shown) may be formed on the insulating layer 121a through the photolithography process, and then the insulating layer 121a and the fifth electrode layer 112c1 are partially removed through the etch process until the fourth dielectric layer 114d is revealed. An opening O1 is formed to reveal the fourth dielectric layer 114d and first sidewalls S1 of the fifth electrode layer 112c1. In some embodiments, the etching process may be performed by exposing the fifth electrode layer 112c1 to a first etchant. The first etchant may include a dry etchant (e.g., a reactive ion etching (RIE) etchant, a plasma etchant, or the like). In some embodiments, the first etchant may have an etching chemistry including one or more tetrafluoromethane (CF₄), fluoroform (CHF₃), chlorine (Cl₂), nitrogen (N₂), argon (Ar), boron trichloride (BCl₃), or the like. In some embodiments, after performing the removal process, any residual photoresist is removed by an ash process or by dissolution with a solvent.

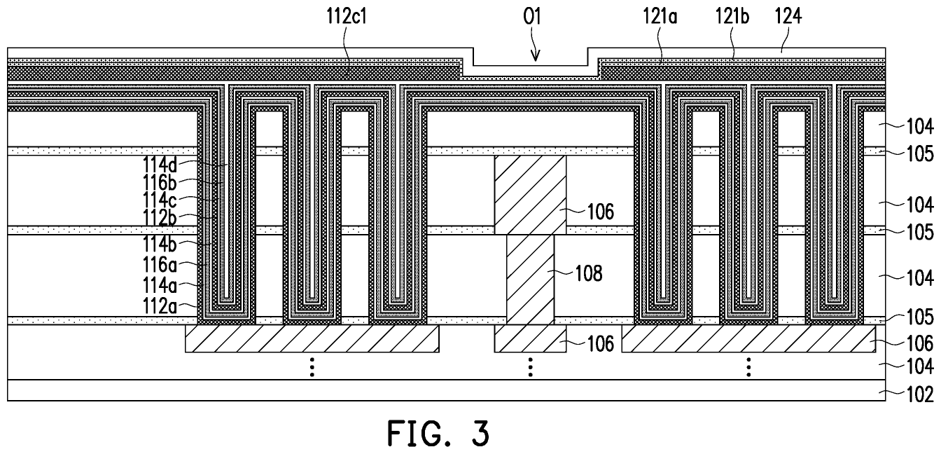

Referring to FIG. 3, an additional insulating layer 121b is deposited on the insulating layer 121a, the first sidewalls S1 of the fifth electrode layer 112c1 and the revealed fourth dielectric layer 114d. In some embodiments, a nitride layer 124 are deposited on the additional insulating layer 121b. In some embodiments, the additional insulating layer 121b and the nitride layer 124 may be each formed by one or more deposition processes (e.g., a PVD process, a CVD process, a PECVD process, or the like). In various embodiments, the additional insulating layer 121b may include silicon dioxide, silicon oxynitride, and/or the like. In various embodiments, the nitride layer 124 may include silicon nitride, silicon oxynitride, and/or the like. In some embodiments, a sum of a thickness of the additional insulating layer 121b and the nitride layer 124 is in a range of between approximately 100 Å and approximately 1500 Å, between approximately 50 Å and approximately 1000 Å, between approximately 250 Å and approximately 7500 Å, approximately 500 Å, or other similar values.

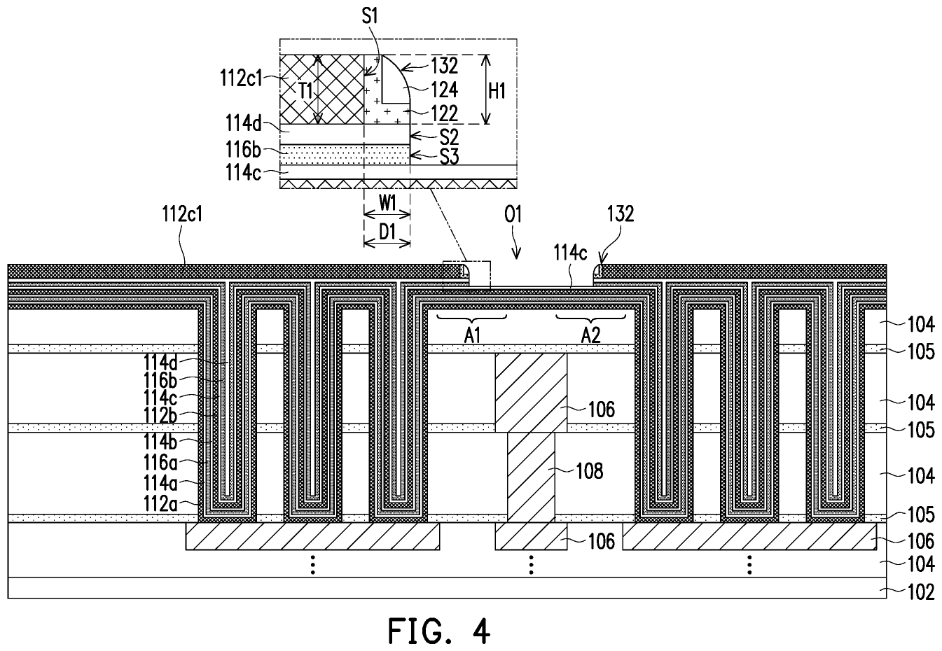

Referring to FIG. 4, in a region A1, a first spacer 132 is formed on a first portion of the fourth dielectric layer 114d to cover the first sidewall S1 of the fifth electrode layer 112c1. Then, the fourth dielectric layer 114d and the fourth electrode layer 116b are patterned by using the fifth electrode layer 112c1 and the first spacer 132 as a mask, to reveal the third dielectric layer 114c, a first sidewall S2 of the fourth dielectric layer 114d and a first sidewall S3 of the fourth electrode layer 116b.

In a region A2, another first spacer 132 is formed in the same process and at same time as the first spacer 132. In region A2, the first spacer 132 is formed on a second portion of the fourth dielectric layer 114d to cover the first sidewall S1 of the fifth electrode layer 112c1. The region A1 and the region A2 are mirror-symmetrical to each other with respect to a center line (as an axis of symmetry) (not shown) of the opening O1. In order to described concisely and clearly, the following description only indicates the example structures and the example processes in the region A1.

The insulating layer 121a, the additional insulating layer 121b and the nitride layer 124 are removed by an etching process including a second etchant. The second etchant removes the insulating layer 121a, the additional insulating layer 121b and the nitride layer 124 horizontally extending over the fifth electrode 112c1 and the fourth dielectric layer 114d, to form the first spacer 132 covering the first sidewall S1 of the fifth electrode layer 112c1 and reveals the fourth electrode layer 114d. In some embodiments, the second etchant may include a dry etchant (e.g., a reactive ion etching (RIE) etchant, a plasma etchant, or the like). In some embodiments, the second etchant may have an etching chemistry including one or more tetrafluoromethane (CF₄), fluoroform (CHF₃), chlorine (Cl₂), nitrogen (N₂), argon (Ar), boron trichloride (BCl₃), or the like.

In some embodiments, portions of the fourth dielectric layer 114d and the fourth electrode layer 116b are subsequently removed by an etching process including a third etchant. Then, the third dielectric layer 114c is revealed. In some embodiments, the third etchant may be a same etchant as the second etchant (e.g., as part of a continuous etching process that defines the first spacer 132), while in other embodiments the third etchant may include an etchant that is separate and different than the second etchant. Since the fourth dielectric layer 114d and the fourth electrode layer 116b are etched according to the first spacer 132, the first spacer 132 has an outermost sidewall that is substantially aligned with the first sidewall S2 of the fourth dielectric layer 114d and the first sidewall S3 of the fourth electrode layer 116b.

In some embodiments, a thickness T1 of the fifth electrode layer 112c1 substantially equals to a height H1 of the first spacer 132. A first lateral offset D1 is between the first sidewall S3 of the fourth electrode layer 116b and the first sidewall S1 of the fifth electrode layer 112c1, and the first lateral offset D1 substantially equals to a maximum width W1 of the first spacer 132. In some embodiments, the first spacer 132 is disposed over a lateral offset region of the fourth electrode layer 116b.

In some embodiments, using the first spacer 132 as the mask to define the fourth electrode layer 116b allows patterning of the fourth dielectric layer 114d and the fourth electrode layer 116b without using a photomask, thereby providing for a relatively low-cost process to form a metal-insulator-metal (MIM) capacitor structure. Moreover, having the first spacer 132 in place during the etching process allows for the first spacer 132 to cover the first sidewall S1 of the fifth electrode layer 112c1 and to prevent conductive byproducts (e.g., from etching the fourth electrode layer 116b) from being re-deposited along the first sidewall S1 of the fifth electrode layer 112c1. By preventing conductive byproducts from being re-deposited along the first sidewall S1 of the fifth electrode layer 112c1, the conductive byproducts cannot form a conductive path between the fourth electrode layer 116b and the fifth electrode layer 112c1, thereby preventing electrical short between the fourth electrode layer 116b and the fifth electrode layer 112c1.

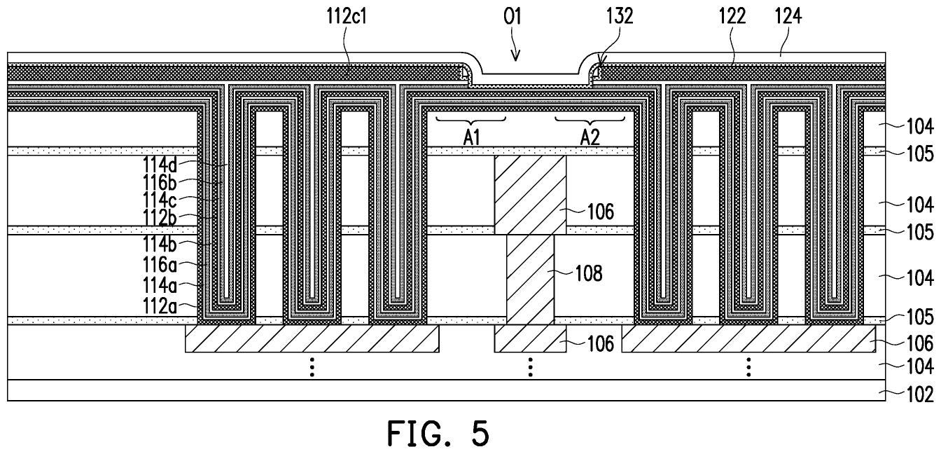

Referring to FIG. 5, unless further description as follows, the definition of the reference symbols and labeled representations are the same as FIG. 3, and will not be repeated herein. An insulating layer 122 is deposited on the patterned fifth electrode layer 112c1, the first spacer 132, the first sidewall S2 of the fourth dielectric layer 114d, the first sidewall S3 of the fourth electrode layer 116b and the revealed third dielectric layer 114c. In some embodiments, a nitride layer 124 are deposited on the insulating layer 122.

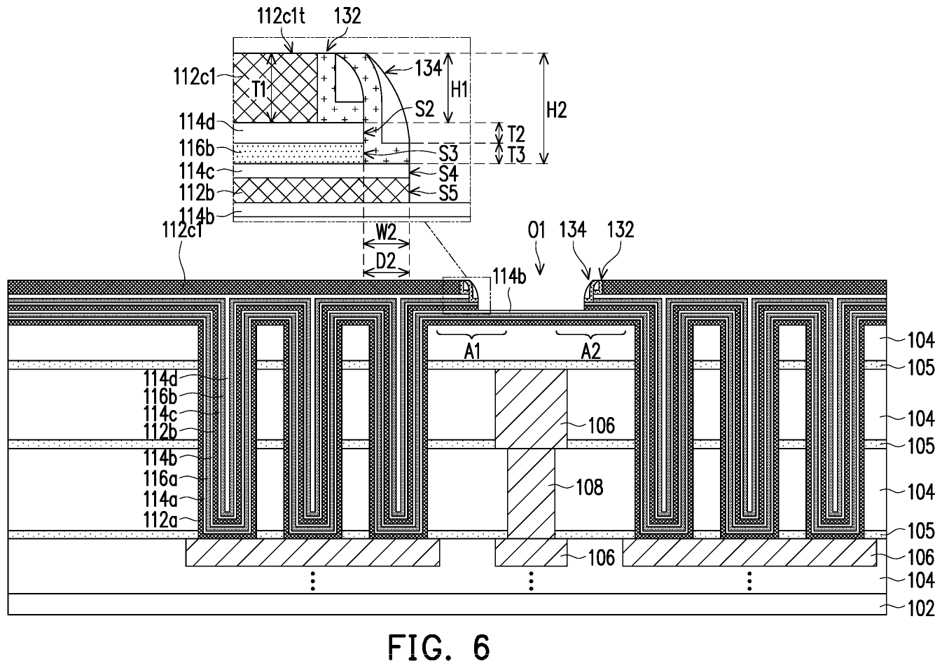

Referring to FIG. 6, a second spacer 134 is formed on a first portion of the third dielectric layer 114c to cover the first spacer 132, the first sidewall S2 of the fourth dielectric layer 114d and the first sidewall S3 of the fourth electrode layer 116b. Then, the third dielectric layer 114c and the third electrode layer 112b are patterned by using the fifth electrode layer 112c1, the first spacer 132 and the second spacer 134 as a mask, to reveal the second dielectric layer 114b, a first sidewall S4 of the third dielectric layer 114c and a first sidewall S5 of the third electrode layer 112b.

The insulating layer 122 and the nitride layer 124 are performed an etching process. to remove the insulating layer 122 and the nitride layer 124 horizontally extending over the fifth electrode 112c1 and the third dielectric layer 114c. Then, the second spacer 134 is formed to cover the first sidewall S2 of the fourth dielectric layer 114d and the first sidewall S3 of the fourth electrode layer 116b. In some embodiments, the etching process may be performed as the same as the etching process including the second etchant, and will not be repeated herein.

In some embodiments, portions of the third dielectric layer 114c and the third electrode layer 112b are subsequently performed an etching process. Then, the second dielectric layer 114b is revealed. In some embodiments, the etching process may be performed as the same as the etching process including the third etchant, and will not be repeated herein. Since the third dielectric layer 114c and the third electrode layer 112b are etched according to the second spacer 134, the second spacer 134 has an outermost sidewall that is substantially aligned with the first sidewall S4 of the third dielectric layer 114c and the first sidewall S5 of the third electrode layer 112b.

In some embodiments, the height H1 of the first spacer 132 is less than a height H2 of the second spacer 134. A sum of a thickness T3 of the fourth electrode layer 116b, a thickness T2 of the fourth dielectric layer 114d and the thickness T1 of the fifth electrode layer 112c1 substantially equals to the height H2 of the second spacer 134. A second lateral offset D2 is between the first sidewall S5 of the third electrode layer 112b and the first sidewall S3 of the fourth electrode layer 116b, and the second lateral offset D2 substantially equals to a maximum width W2 of the second spacer 134. In some embodiments, the maximum width W2 of the second spacer 134 is greater than the maximum width W1 of the first spacer 132. In some embodiments, the maximum width W2 of the second spacer 134 equals to the maximum width W1 of the first spacer 132. In some embodiments, the maximum width W2 of the second spacer 134 is less than the maximum width W1 of the first spacer 132. In some embodiments, the second spacer 134 is disposed over a lateral offset region of the third electrode layer 112b. In some embodiments, a top surface 112c1t of the fifth electrode layer 112c1 substantially levels to a top surface of the first spacer 132 and a top surface of the second spacer 134.

In some embodiments, the second spacer 134 has the same effects as the first spacer 132. Using the second spacer 134 as the mask to define the third electrode layer 112b allows for removing the third dielectric layer 114c and the third electrode layer 112b without a photomask, thereby providing for a relatively low cost process to form the MIM capacitor structure and preventing electrical shorting between the fourth electrode layer 116b and the third electrode layer 112b.

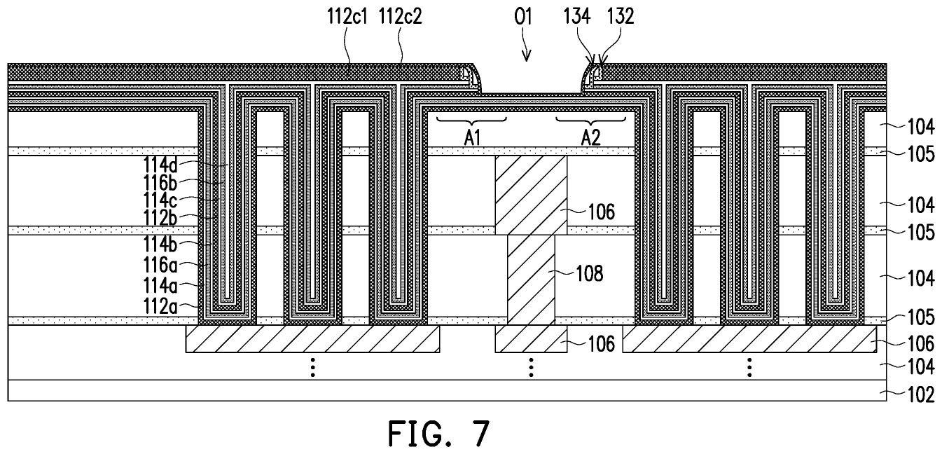

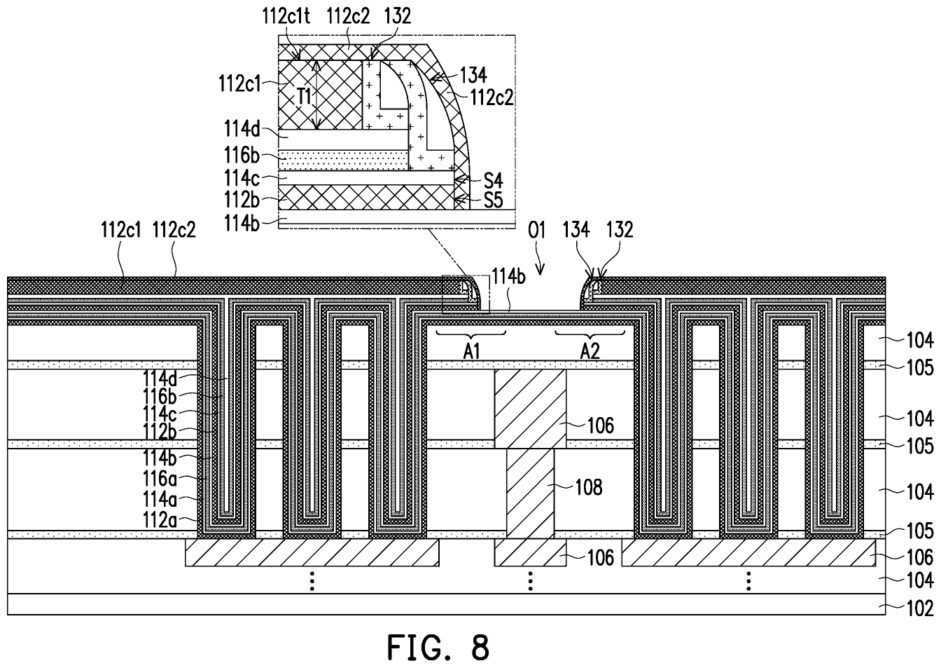

Referring FIG. 7 and FIG. 8, a first conductive layer 112c2 is formed on the fifth electrode layer 112c1, the first spacer 132, and the second spacer 134, and the first sidewall S5 of the third electrode layer 112b to electrically connect the fifth electrode layer 112c1 and the third electrode layer 112b.

In FIG. 7, the first conductive layer 112c2 is formed on the fifth electrode layer 112c1, the first spacer 132, and the second spacer 134, the first sidewall S4 of the third dielectric layer 114c, the first sidewall S5 of the third electrode layer 112b and the revealed second dielectric layer 114b. The first conductive layer 112c2 may be deposited by, for example, ALD, CVD, PVD, electrochemical plating, electroless plating, sputtering, some other deposition process, or a combination of the foregoing. The first conductive layer 112c2 may be conductive and may be or include, for example, titanium (Ti), titanium nitride (TiN), tantalum (Ta), tantalum nitride (TaN), aluminum (Al), aluminum titanium (AlTi), some other conductive material, or a combination of the foregoing. In some embodiments, the first conductive layer 112c2 is deposited with a thickness between approximately 10 angstroms (Å) and approximately 1000 Å.

In FIG. 8, the first conductive layer 112c2 is patterned by a photolithography process followed by an etch process, and a photomask is used in the photolithography process. In other words, a patterned photoresist layer (not shown) may be formed on the first conductive layer 112c2 through the photolithography process, and then the first conductive layer 112c2 is partially removed through the etch process until the second dielectric layer 114b is revealed. In some embodiments, the etching process may be performed by exposing the first conductive layer 112c2 to a fourth etchant. The fourth etchant may include a dry etchant (e.g., a reactive ion etching (RIE) etchant, a plasma etchant, or the like). In some embodiments, the fourth etchant may have an etching chemistry including one or more tetrafluoromethane (CF₄), fluoroform (CHF₃), chlorine (Cl₂), nitrogen (N₂), argon (Ar), boron trichloride (BCl₃), or the like. In some embodiments, after performing the removal process, any residual photoresist is removed by an ash process or by dissolution with a solvent.

The first conductive layer 112c2 is formed on the fifth electrode layer 112c1, the first spacer 132, and the second spacer 134, the first sidewall S4 of the third dielectric layer 114c, the first sidewall S5 of the third electrode layer 112b to electrically connect the fifth electrode layer 112c1 and the third electrode layer 112b. The first conductive layer 112c2 is in contact with the top surface 112c1t of the fifth electrode layer 112c1 and the first sidewall S5 of the third electrode layer 112b. The first conductive layer 112c2 is spaced apart from the fourth electrode layer 116b by the first spacer 132 and the second spacer 134.

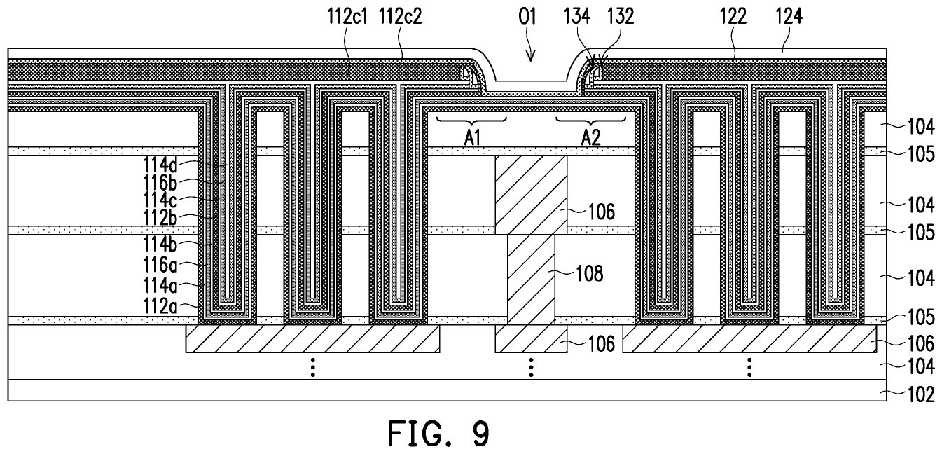

Referring to FIG. 9 to FIG. 12, a third spacer 136 may be formed by the same processes and the same materials as the first spacer 132. Unless further description as follows, the processes, the materials and the effects of forming the third spacer 136 are the same as the first spacer 132 of FIG. 3 to FIG. 4, and will not be repeated herein. A fourth spacer 138 may be formed by the same processes and the same materials as the second spacer 134. Unless further description as follows, the processes, the materials and the effects of forming the fourth spacer 138 are the same as the second spacer 134 of FIG. 5 to FIG. 6, and will not be repeated herein.

The third spacer 136 is formed on a first portion of the second dielectric layer 114b to cover a portion of the first conductive layer 112c2. Then, the second dielectric layer 114b and the second electrode layer 116a are patterned by using the first conductive layer 112c2 and the third spacer 136 as a mask, to reveal the first dielectric layer 114a, a first sidewall S6 of the second dielectric layer 114b and a first sidewall S7 of the second electrode layer 116a.

Since the second dielectric layer 114b and the second electrode layer 116a are etched according to the third spacer 136, the third spacer 136 has an outermost sidewall that is substantially aligned with the first sidewall S6 of the second dielectric layer 114b and a first sidewall S7 of the second electrode layer 116a.

The fourth spacer 138 is formed on a first portion of the first dielectric layer 114a to cover the third spacer 136, the first sidewall S6 of the second dielectric layer 114b and a first sidewall S7 of the second electrode layer 116a. Then, the first dielectric layer 114a and the first electrode layer 112a are patterned by using the first conductive layer 112c2, the third spacer 136 and the fourth spacer 138 as a mask, to reveal the insulating layer 104, a first sidewall S8 of the first dielectric layer 114a and a first sidewall S9 of the first electrode layer 112a.

Since the first dielectric layer 114a and the first electrode layer 112a are etched according to the fourth spacer 138, the fourth spacer 138 has an outermost sidewall that is substantially aligned with the first sidewall S8 of the first dielectric layer 114a and the first sidewall S9 of the first electrode layer 112a.

In some embodiments, a height H3 of the third spacer 136 is less than a height H4 of the fourth spacer 138. The height H2 of the second spacer 134 is less than the height H3 of the third spacer 136. The height H1 of the first spacer 132 is less than the height H2 of the second spacer 134.

A third lateral offset D3 is between the first sidewall S5 of the third electrode layer 112b and the first sidewall S7 of the second electrode layer 116a, and the third lateral offset D3 substantially equals to a maximum width W3 of the third spacer 136. In some embodiments, the third spacer 136 is disposed over a lateral offset region of the second electrode layer 116a. A fourth lateral offset D4 is between the first sidewall S9 of the first electrode layer 112a and the first sidewall S7 of the second electrode layer 116a, and the fourth lateral offset substantially equals to a maximum width W4 of the fourth spacer 138. In some embodiments, the fourth spacer 138 is disposed over a lateral offset region of the first electrode layer 112a.

In some embodiments, a top surface 112c2t of the first conductive layer 112c2 substantially levels to a top surface of the third spacer 136 and a top surface of the fourth spacer 138. The different between the top surfaces of the spacers (the third spacer 136, the fourth spacer 138 and the top surfaces of the spacers (the first spacer 132, the second spacer 134 substantially equals to a thickness of the first conductive layer 112c2.

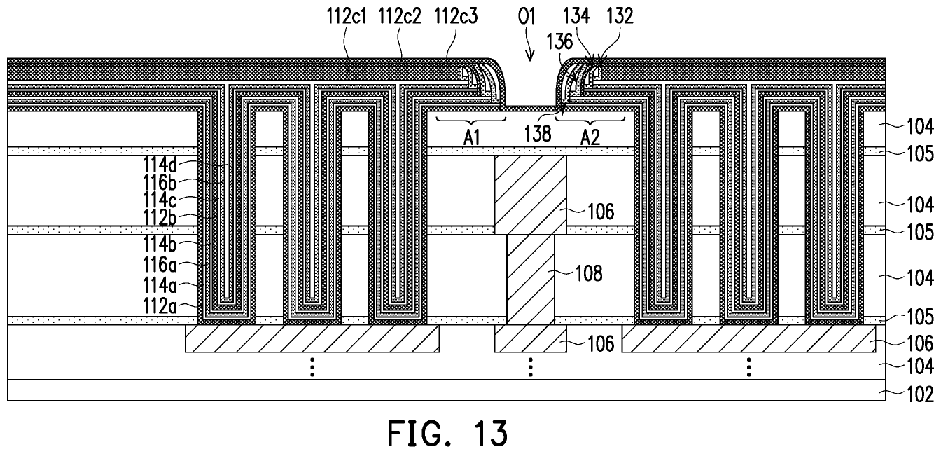

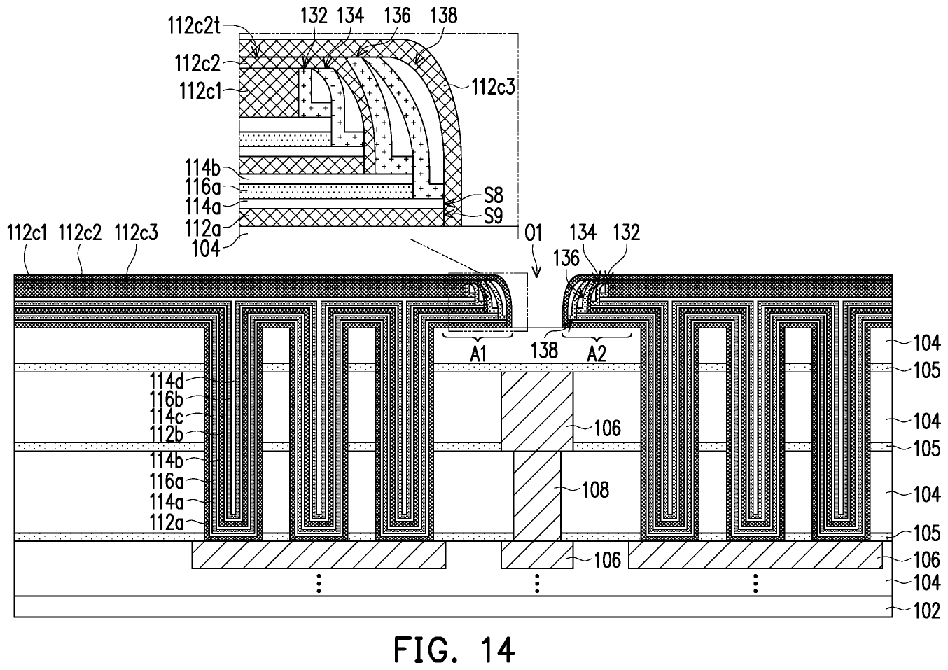

Referring FIG. 13 and FIG. 14, a second conductive layer 112c3 is formed on the top surface 112c2t of the first conductive layer 112c2, the third spacer 136, and the fourth spacer 138, and the first sidewall S9 of the first electrode layer 112a to electrically connect the fifth electrode layer 112c1 and the first electrode layer 112a, and to electrically connect the third electrode layer 112b and the first electrode layer 112a.

In FIG. 13, the second conductive layer 112c3 is formed on the first conductive layer 112c2, the third spacer 136, the fourth spacer 138, the first sidewall S8 of the first dielectric layer 114a, the first sidewall S9 of the first electrode layer 112a and the revealed insulating layer 104. The second conductive layer 112c3 may be deposited by the same processes and the same materials as the first conductive layer 112c2.

In FIG. 14, the second conductive layer 112c3 is patterned by a photolithography process followed by an etch process, and a photomask is used in the photolithography process. In other words, a patterned photoresist layer (not shown) may be formed on the second conductive layer 112c3 through the photolithography process, and then the second conductive layer 112c3 is partially removed through the etch process until the insulating layer 104 is revealed. The second conductive layer 112c3 is in contact with the top surface 112c2t of first conductive layer 112c2 and the first sidewall S9 of the first electrode layer 112a. The second conductive layer 112c3 is spaced apart from the second electrode layer 116a by the third spacer 136 and the fourth spacer 138.

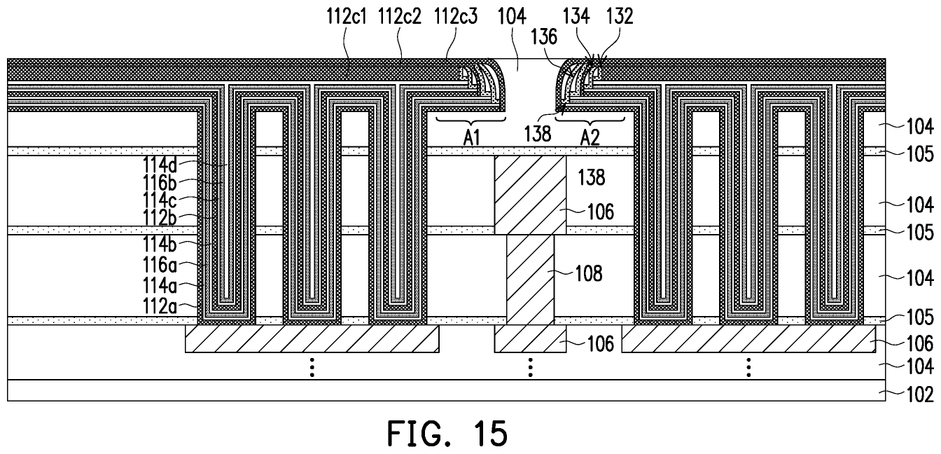

Referring to FIG. 15, an insulating material is deposited on the second conductive layer 112c3 and fills up the opening O1. The insulating material may be any suitable insulating materials. Any suitable planarization process (such as Chemical-Mechanical Polishing (CMP)) may be performed on the insulating material until reveal the second conductive layer 112c3. Then, an insulating layer 104 is formed within opening O1. In some embodiments, a top surface of the second conductive layer 112c3 substantially levels to a top surface of the insulating layer 104.

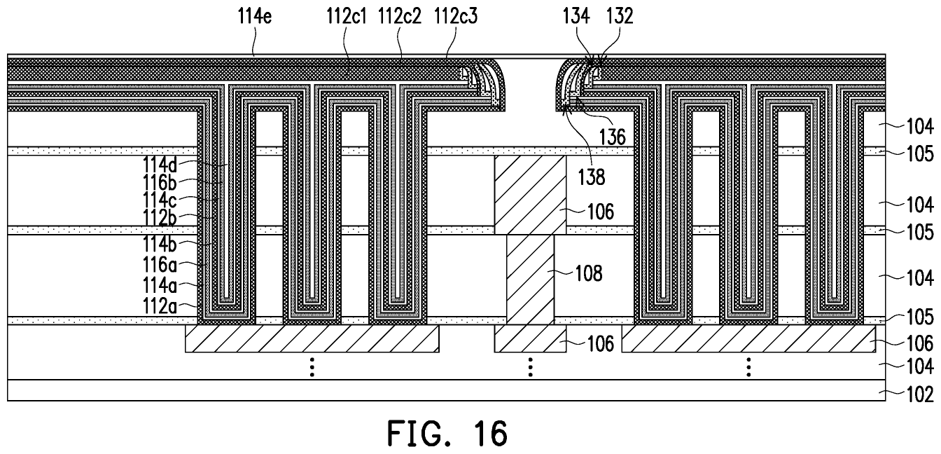

Referring to FIG. 16, a fifth dielectric layer 114e is formed on the second conductive layer 112c3 and the insulating layer 104 by the same processes and the same materials as the dielectric layers 114a-114d.

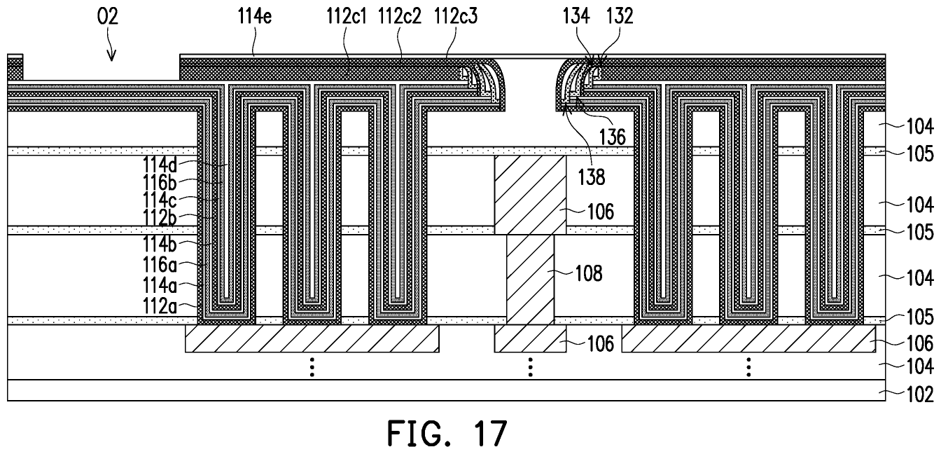

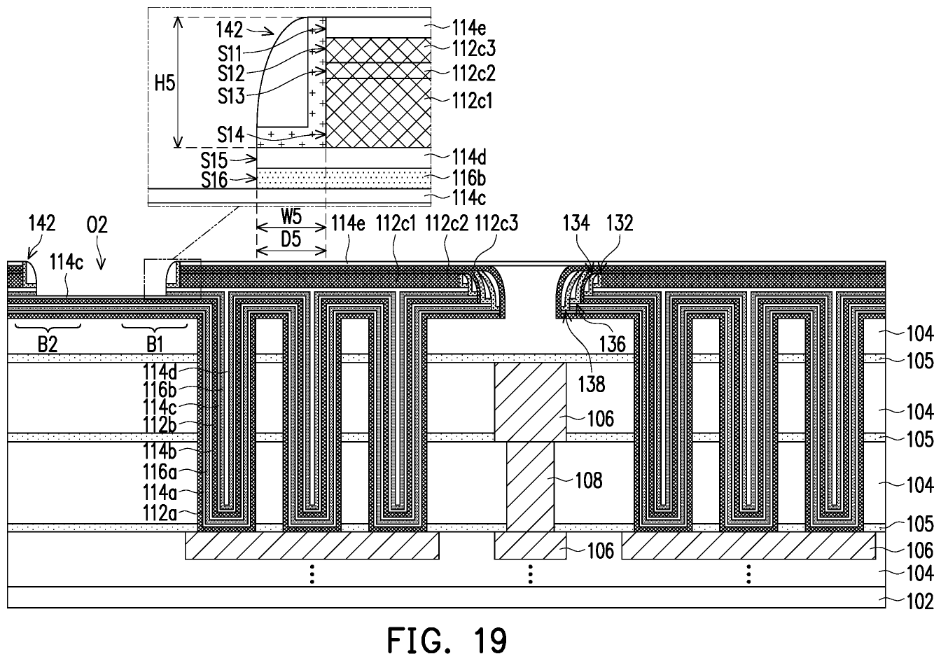

Referring to FIG. 17, the fifth dielectric layer 114e, the second conductive layer 112c3, the first conductive layer 112c2 and the fifth electrode layer 112c1 are patterned by a photolithography process followed by an etch process, and a photomask is used in the photolithography process. In other words, a patterned photoresist layer (not shown) may be formed on the fifth dielectric layer 114e through the photolithography process, and then the fifth dielectric layer 114e, the second conductive layer 112c3, the first conductive layer 112c2 and the fifth electrode layer 112c1 are partially removed through the etch process until the fourth dielectric layer 114d is revealed. An opening O2 is formed to reveal the fourth dielectric layer 114d, second sidewall(s) S11 of the fifth dielectric layer 114e, second sidewall(s) S12 of the second conductive layer 112c3, sidewalls S13 of the first conductive layer 112c2, and sidewall(s) S14 of the fifth electrode layer 112c1 (shown in FIG. 19).

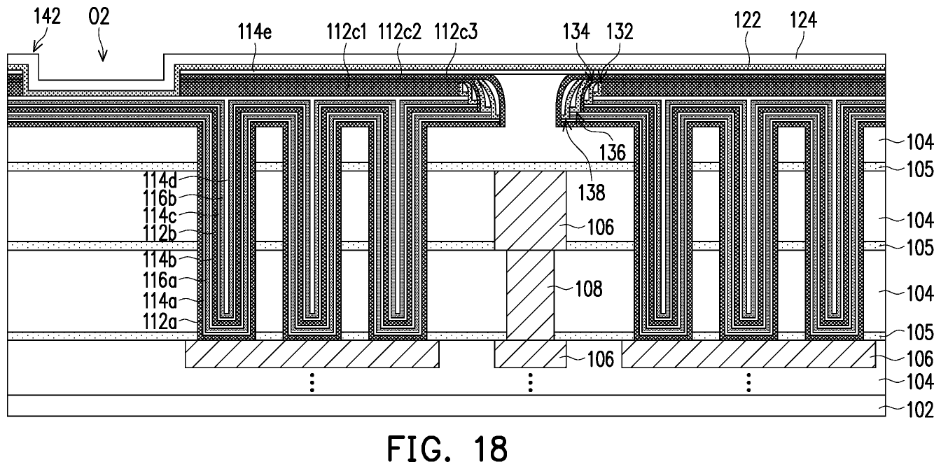

Referring to FIGS. 18 to 19, a fifth spacer 142 in a region B1 may be formed by the same processes and the same materials as the first spacer 132 after depositing the insulating layer 122 and the nitride layer 124. Unless further description as follows, the processes, the materials and the effects of forming the fifth spacer 142 are the same as the first spacer 132 of FIG. 3 to FIG. 4, and will not be repeated herein.

In a region B1, the fifth spacer 142 is formed on a third portion of the fourth dielectric layer 114d to cover the second sidewall S11 of the fifth dielectric layer 114e, the second sidewall S12 of the second conductive layer 112c3, the second sidewall S13 of the first conductive layer 112c2, and the second sidewall S14 of the fifth electrode layer 112c1. Then, the fourth dielectric layer 114d and the fourth electrode layer 116b are patterned by using the fifth dielectric layer 114e and the fifth spacer 142 as a mask, to reveal the third dielectric layer 114c, a second sidewall S15 of the fourth dielectric layer 114d and a second sidewall S16 of the fourth electrode layer 116b.

In a region B2, an additional fifth spacer 142 is formed in the same process and at same time as the fifth spacer 142. In region A2, the additional fifth spacer 142 is formed on a fourth portion of the fourth dielectric layer 114d to cover the second sidewall S11 of the fifth dielectric layer 114e, the second sidewall S12 of the second conductive layer 112c3, the second sidewall S13 of the first conductive layer 112c2, and the second sidewall S14 of the fifth electrode layer 112c1. The region B1 and the region B2 are mirror-symmetrical to each other with respect to a center line (as an axis of symmetry) (not shown) of the opening 02. In order to described concisely and clearly, the following description only indicates the example structures and the example processes in the region B1.

Since the fourth dielectric layer 114d and the fourth electrode layer 116b are etched according to the fifth spacer 142, the fifth spacer 142 has an outermost sidewall that is substantially aligned with the second sidewall S15 of the fourth dielectric layer 114d and the second sidewall S16 of the fourth electrode layer 116b.

In some embodiments, a height H5 of the fifth spacer 142 substantially equals to a sum of a thickness T1 of the fifth electrode layer 112c1, a thickness of the first conductive layer 112c2, a thickness of the second conductive layer 112c3, and a thickness of the fifth dielectric layer 114e. In some embodiments, a height H5 of the fifth spacer 142 is greater than the height H1 of the first spacer 132. A fifth lateral offset D5 is between the second sidewall S16 of the fourth electrode layer 116b and the second sidewall S14 of the fifth electrode layer 112c1, and the fifth lateral offset D5 substantially equals to a maximum width W5 of the fifth spacer 142. In some embodiments, the fifth spacer 142 is disposed over a lateral offset region of the fourth electrode layer 116b.

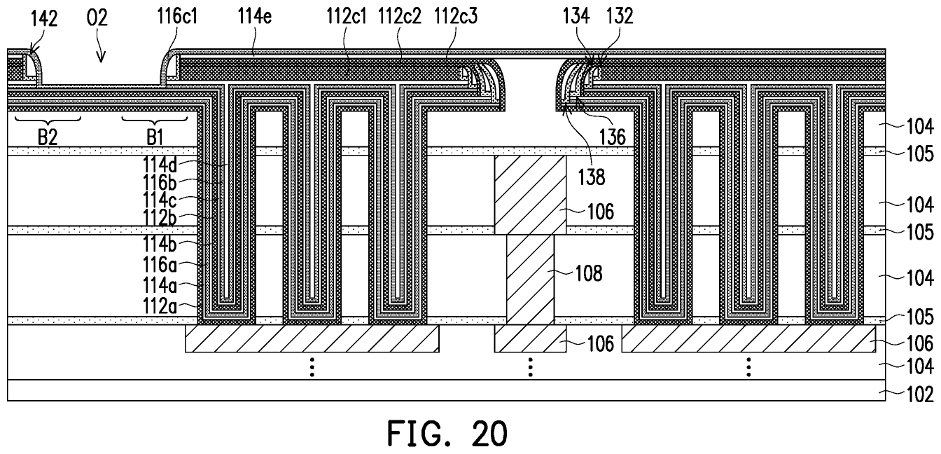

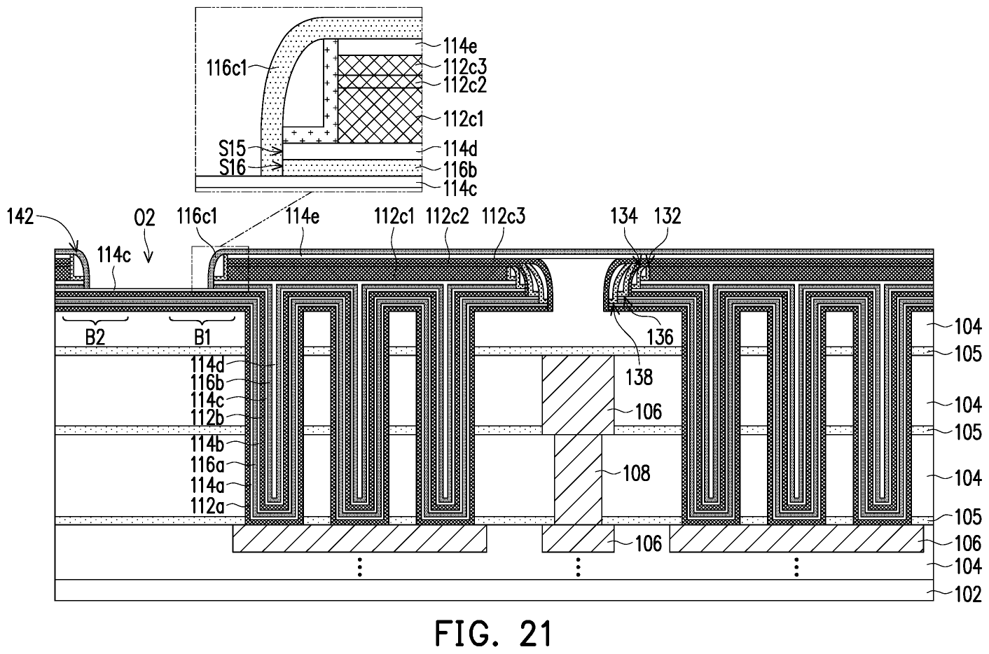

Referring to FIGS. 20 to 21, a third conductive layer 116c1 is formed on the fifth dielectric layer 114e, the fifth spacer 142 and the second sidewall S16 of the fourth electrode layer 116b to be in contact with the second sidewall S16 of the fourth electrode layer 116b. The third conductive layer 116c1 is electrically connected to the fourth electrode layer 116b. Unless further description as follows, the processes and the materials of forming the third conductive layer 116c1 are the same as the first conductive layer 112c2 of FIG. 7 to FIG. 8, and will not be repeated herein.

The third conductive layer 116c1 is patterned by a photolithography process followed by an etch process, and a photomask is used in the photolithography process. In other words, a patterned photoresist layer (not shown) may be formed on the third conductive layer 116c1 through the photolithography process, and then the third conductive layer 116c1 is partially removed through the etch process until the third dielectric layer 114c is revealed.

The third conductive layer 116c1 is formed on the fifth dielectric layer 114e, the fifth spacer 142, the second sidewall S15 of the fourth dielectric layer 114d, the second sidewall S16 of the fourth electrode layer 116b and revealed the third dielectric layer 114c. The third conductive layer 116c1 is spaced apart from the fifth electrode layer 112c1 by the fifth spacer 142.

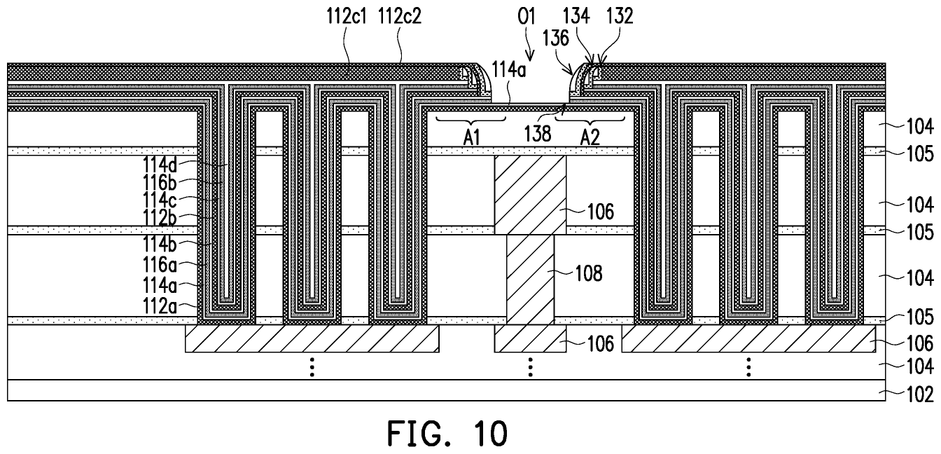

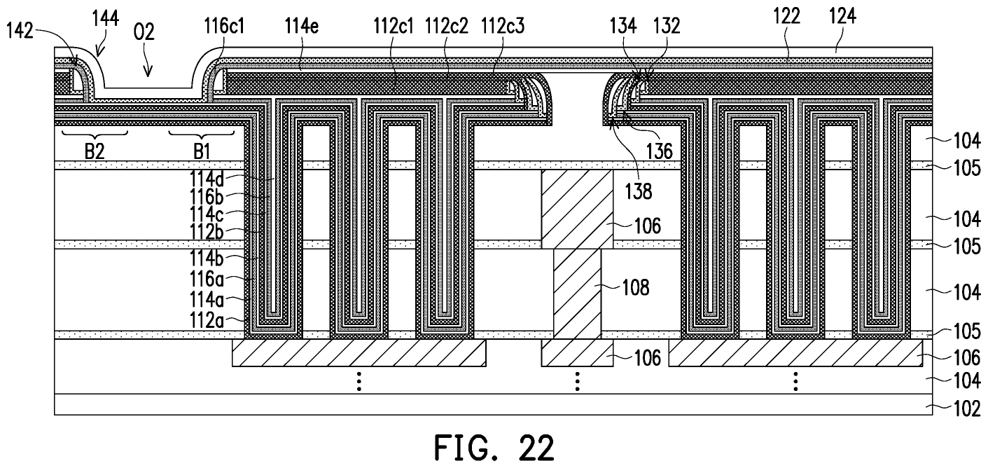

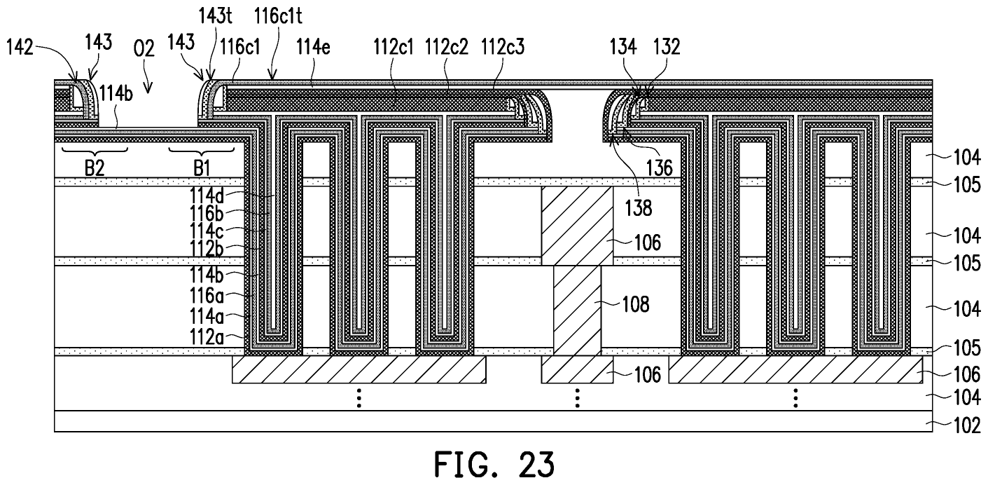

Referring to FIGS. 22 to 23, a spacer structure 143 may be formed by the same processes and the materials as the third spacer 136 after depositing the insulating layer 122 and the nitride layer 124. Unless further description as follows, the processes, the materials and the effects as of forming the spacer structure 143 are the same as the third spacer 136 of FIG. 9 to FIG. 10, and will not be repeated herein.

The spacer structure 143 is formed on a second portion of the third dielectric layer 114c to cover a portion of the third conductive layer 116c1. Then, the third dielectric layer 114c and the third electrode layer 112b are patterned by using the third conductive layer 116c1 and the spacer structure 143 as a mask, to reveal the second dielectric layer 114b, a second sidewall S17 of the third dielectric layer 114c and a second sidewall S18 of the third electrode layer 112b (shown in FIG. 19). In some embodiments, a top surface 116c1t of the third conductive layer 116c1 substantially levels to a top surface 143t of the spacer structure 143.

Since the third dielectric layer 114c and the third electrode layer 112b are etched according to the spacer structure 143, the spacer structure 143 has an outermost sidewall that is substantially aligned with the second sidewall S17 of the third dielectric layer 114c and the second sidewall S18 of the third electrode layer 112b.

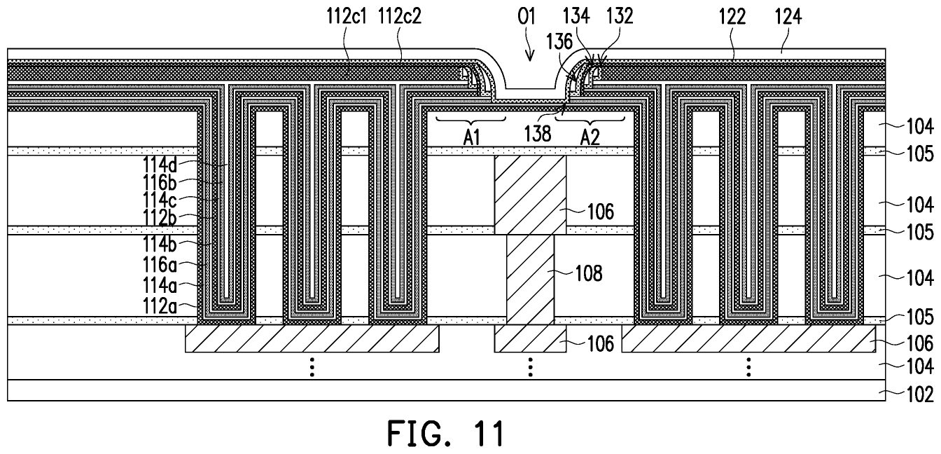

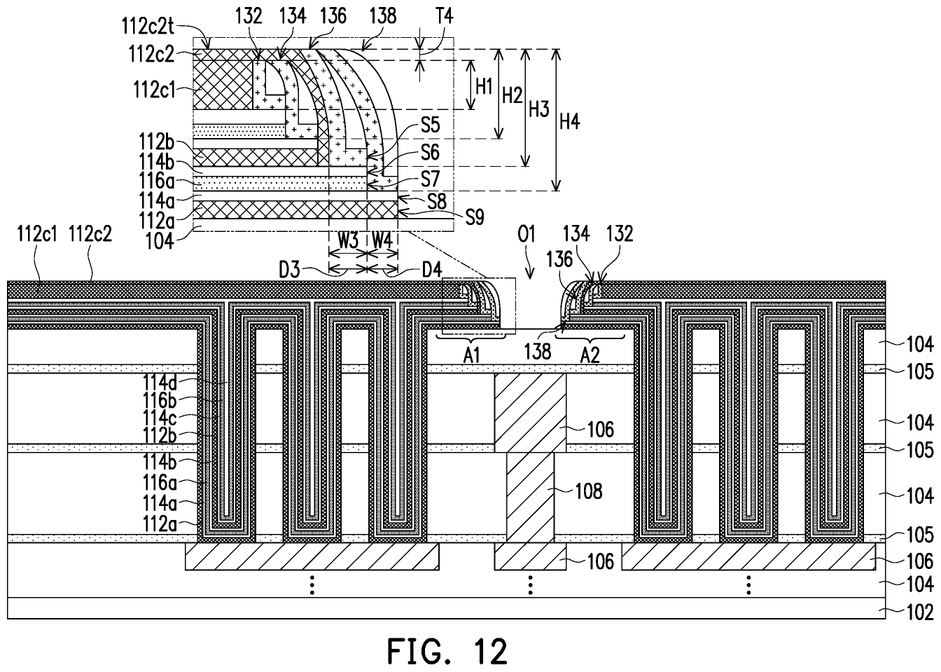

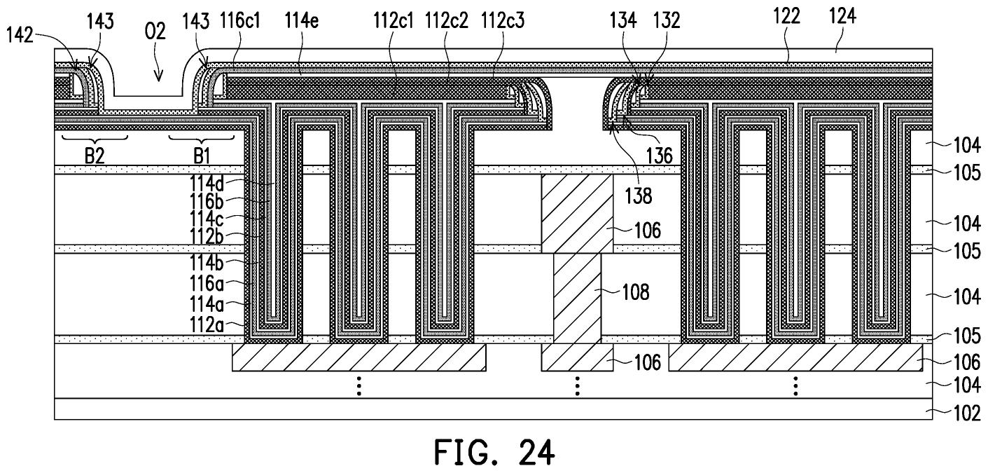

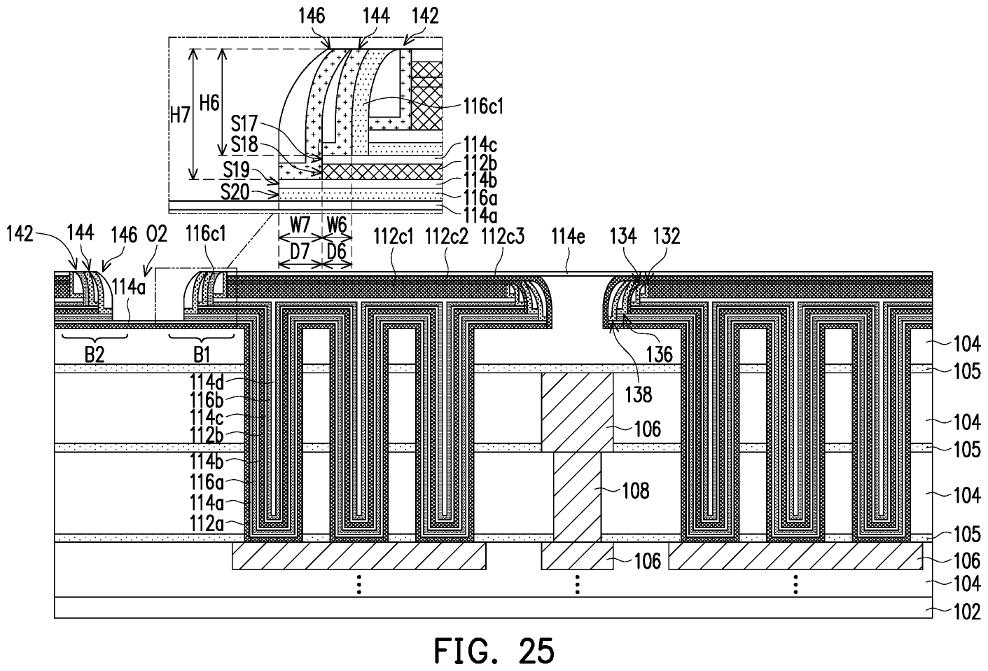

Referring to FIGS. 24 to 25, a sixth spacer 144 is formed by removing a portion of the spacer structure 143 and a seventh spacer 146 is formed during a same process. The seventh spacer 146 may be formed by the same processes and the materials as the fourth spacer 138 after depositing the insulating layer 122 and the nitride layer 124. Unless further description as follows, the processes, the materials and the effects of forming the seventh spacer 146 are the same as the fourth spacer 138 of FIG. 11 to FIG. 12, and will not be repeated herein.

After performing an etching process including the second etchant, the insulating layer 122 and the nitride layer 124 horizontally extending over the third conductive layer 116c1 and the second dielectric layer 114b is removed. Then, the etching process also removes the third conductive layer 116c1 horizontally extending over the fifth spacer 142 and the fifth dielectric layer 114e, and removes a portion of the spacer structure 143 and portions of the insulating layer 122 and the nitride layer 124. The sixth spacer 144 and the seventh spacer 146 are formed.

A height H6 of the sixth spacer 144 is less than a height of the spacer structure 143. Except for the height, the property and the arrangement of the sixth spacer 144 are the same as the spacer structure 143, and will not be repeated herein.

The seventh spacer 146 is formed on a second portion of the second dielectric layer 114b to cover the sixth spacer 144, the second sidewall S17 of the third dielectric layer 114c and the second sidewall S18 of the third electrode layer 112b. Then, the second dielectric layer 114b and the second electrode layer 116a are patterned by using the fifth dielectric layer 114e, the fifth spacer 142, the third conductive layer 116c1, the sixth spacer 144 and the seventh spacer 146 as a mask, to reveal the first dielectric layer 114a, a second sidewall S19 of the second dielectric layer 114b and a second sidewall S20 of the second electrode layer 116a (shown in FIG. 25).

Since the second dielectric layer 114b and the second electrode layer 116a are etched according to the seventh spacer 146, the seventh spacer 146 has an outermost sidewall that is substantially aligned with the second sidewall S19 of the second dielectric layer 114b and the second sidewall S20 of the second electrode layer 116a.

The seventh spacer 146 substantially levels to the third conductive layer 116c1, the sixth spacer 144, and the fifth spacer 142. A height H7 of the seventh spacer 146 is greater than the height H6 of the sixth spacer 144. The height H6 of the sixth spacer 144 is greater than the height H5 of the fifth spacer 142. A sixth lateral offset D6 is between the second sidewall S16 of the fourth electrode layer 116b and the second sidewall S18 of the third electrode layer 112b, and the sixth lateral offset D6 substantially equals to a maximum width W6 of the sixth spacer 144. In some embodiments, the sixth spacer 144 is disposed over a lateral offset region of the third electrode layer 112b. A seventh lateral offset D7 is between the second sidewall S20 of the second electrode layer 116a and the second sidewall S18 of the third electrode layer 112b, and the seventh lateral offset D7 substantially equals to a maximum width W7 of the seventh spacer 146. In some embodiments, the seventh spacer 146 is disposed over a lateral offset region of the second electrode layer 116a.

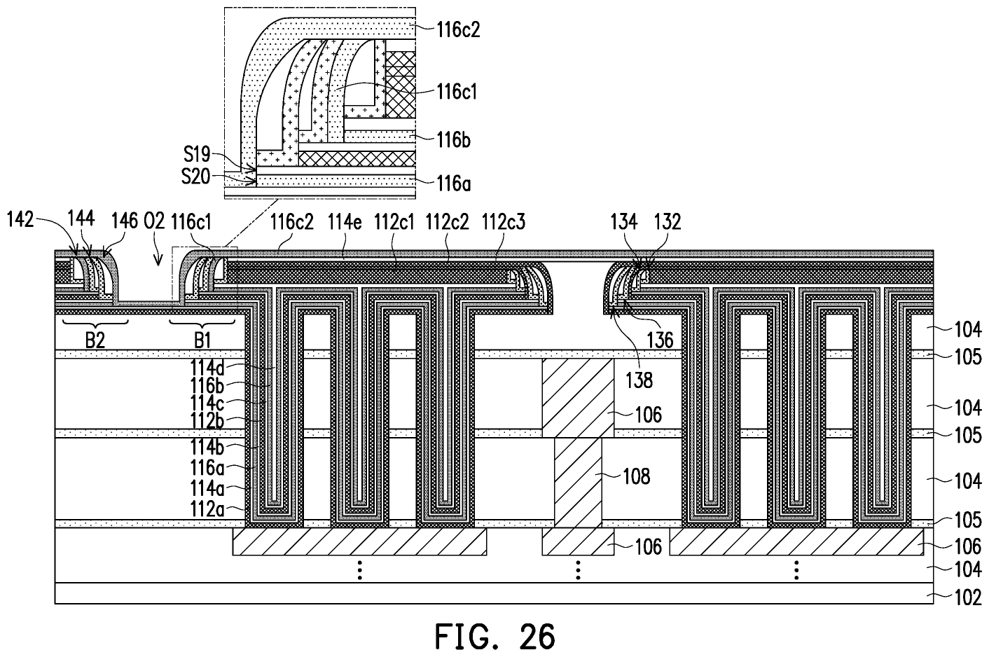

Referring FIG. 26, a sixth electrode layer 116c2 may be deposited by the same processes as the second conductive layer 112c3 of FIG. 13. In some embodiments, the sixth electrode layer 116c2 may be formed by the same materials as the fourth electrode layer 116b and the second conductive layer 112c3.

The sixth electrode layer 116c2 is formed on the fifth dielectric layer 114e, the fifth spacer 142, the third conductive layer 116c1, the sixth spacer 144, the seventh spacer 146, the second sidewall S19 of the second dielectric layer 114b, the second sidewall S20 of the second electrode layer 116a and the first dielectric layer 114a, to electrically connect the sixth electrode layer 116c2 and the fourth electrode layer 116b, and to electrically connect sixth electrode layer 116c2 and the second sidewall S20 of the second electrode layer 116a. The sixth electrode layer 116c2 is spaced apart from the third electrode layer 112b by the sixth spacer 144 and the seventh spacer 146.

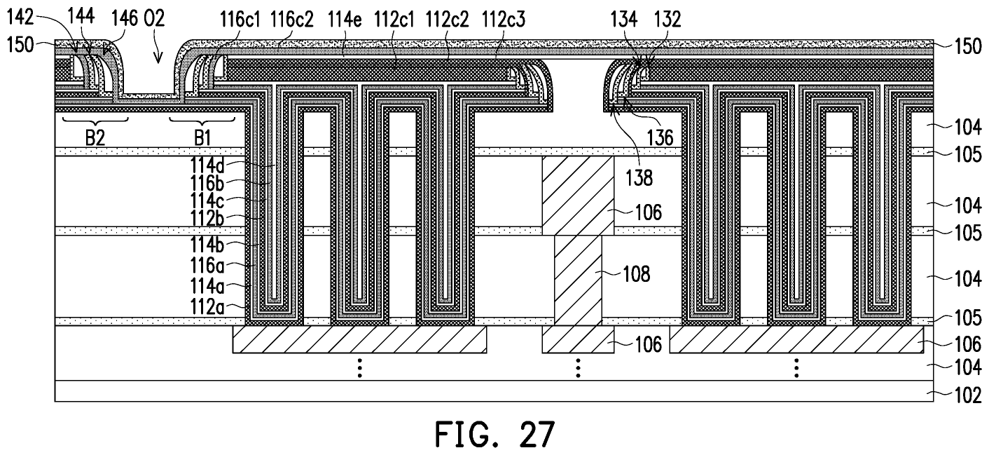

Referring FIG. 27, a capping layer 150 is formed on the sixth electrode layer 116c2. The capping layer 150 is formed by, for example, chemical vapor deposition (CVD), physical vapor deposition (PVD), atomic layer deposition (ALD), some other process, or a combination of the foregoing. In some embodiments, the capping layer 150 may include a dielectric material such as silicon oxynitride, silicon oxycarbide, or the like.

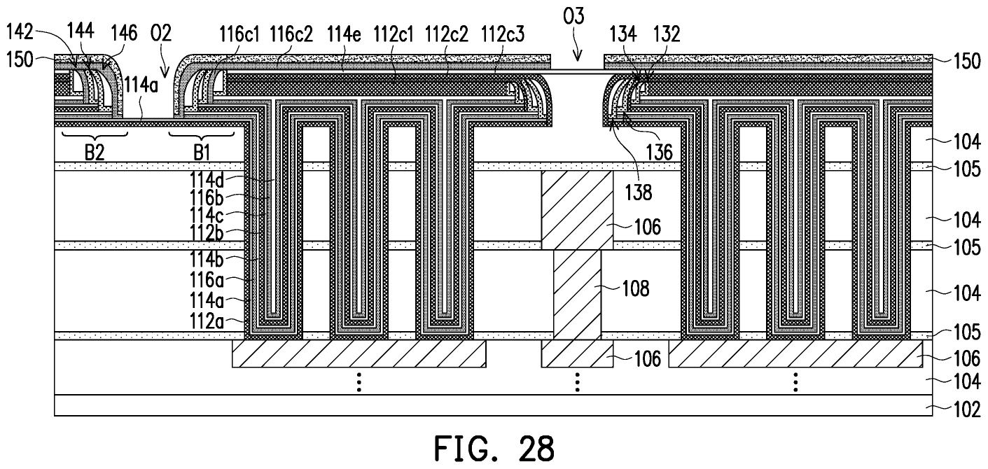

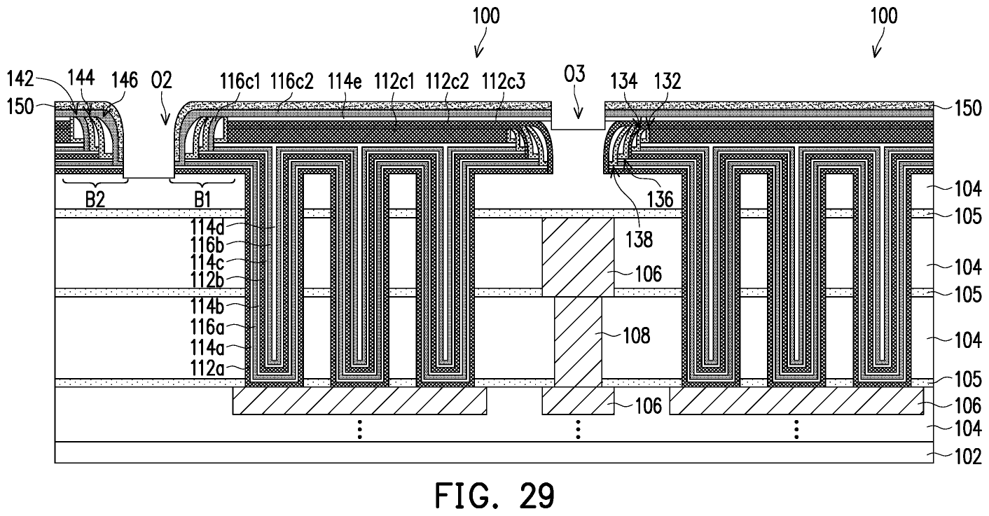

Referring FIG. 28 and FIG. 29, any suitable photomasks may be used in the photolithography process to reveal the insulating layer 104 in the opening O2 and the insulating layer 104 in an opening O3.

In FIG. 28, the capping layer 150 and the sixth electrode layer 116c2 are patterned by a photolithography process followed by an etch process, and a photomask is used in the photolithography process. In other words, a patterned photoresist layer (not shown) may be formed on the capping layer 150 through the photolithography process, and then the capping layer 150 and the sixth electrode layer 116c2 are partially removed through the etch process until the first dielectric layer 114a is revealed in the opening O2 and opening O3.

In FIG. 29, the first dielectric layer 114a and the first electrode layer 112a are patterned by a photolithography process followed by an etch process, and a photomask is used in the photolithography process. In other words, a patterned photoresist layer (not shown) may be formed on the first dielectric layer 114a through the photolithography process, and then the first dielectric layer 114a and the first electrode layer 112a are partially removed through the etch process until the insulating layer 104 is revealed in the opening O2 and opening O3. Recesses of the insulating layer 104 are formed within the insulating layer 104 in the opening O2 and opening O3. Then, MIM capacitor structures 100 are formed. A single MIM capacitor structure 100 is an asymmetrical structure. The adjacent MIM capacitor structures 100 may be mirror-symmetrical to each other.

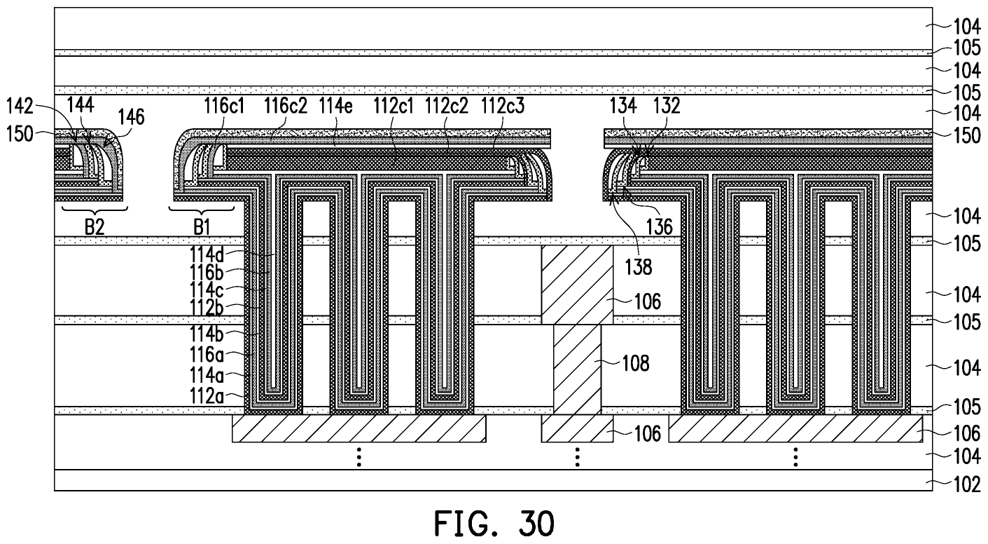

Referring FIG. 30, an insulating material is deposited on the capping layer 150 and fills up the opening O2 and the opening O3 to form the insulating layer 104. The insulating material may be any suitable insulating materials. Any suitable planarization process (such as Chemical-Mechanical Polishing (CMP)) may be performed on the insulating material. Then, the etch stop layers 105 and the insulating layer 104 may be alternatively formed on the insulating layer 104 until to a desire stack.

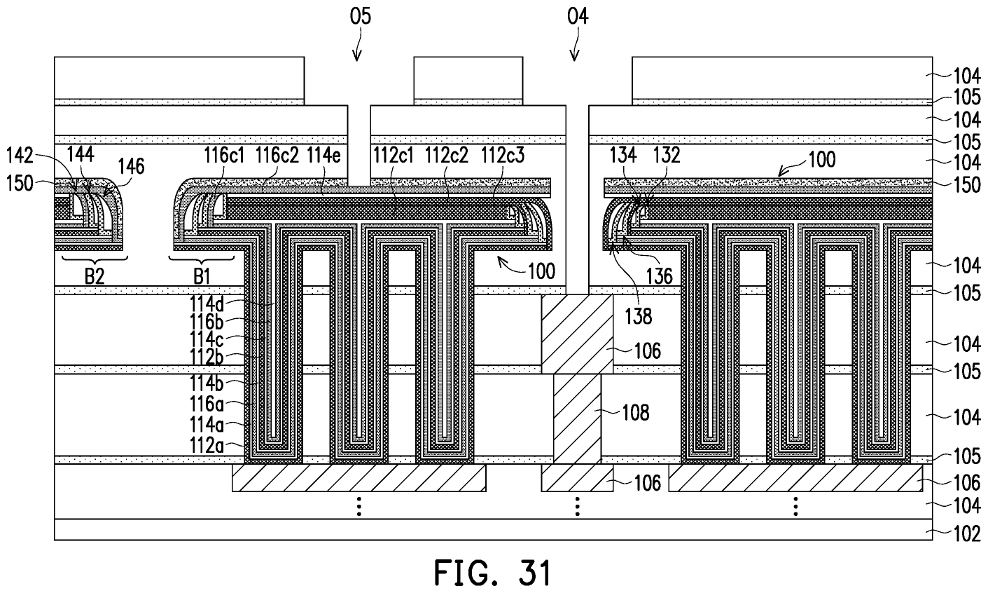

Referring FIG. 31, the insulating layer 104 and the etch stop layers 105 are patterned by a photolithography process followed by an etch process, and a photomask is used in the photolithography process. In other words, a patterned photoresist layer (not shown) may be formed on the insulating layer 104 through the photolithography process, and then the insulating layer 104 and the etch stop layers 105 are partially removed through the etch process until the interconnect wirings 106 disposed between two adjacent MIM capacitor structures 100 are revealed in an opening O4 and the sixth electrode layer 116c2 is revealed in an opening O5.

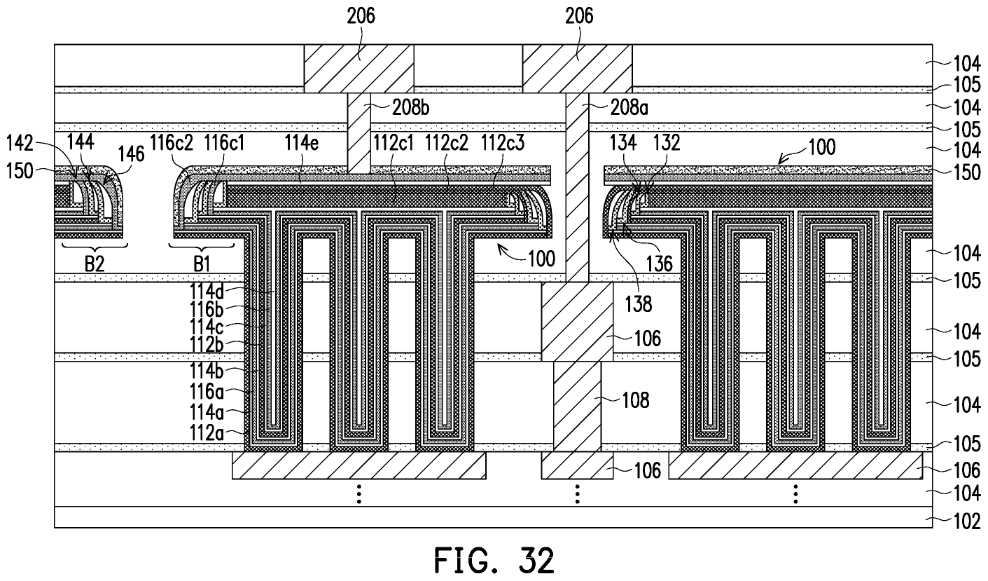

Referring FIG. 32, the conductive material may fill up with the opening O4 and the opening O5 by a deposition process and/or a plating process (e.g., electroplating, electro-less plating, etc.). In various embodiments, the conductive material may include copper, aluminum, or the like. After forming the conductive material within the opening O4 and the opening O5, a planarization process may be performed to remove excess of the conductive material from over the insulating layer 104 and to form a first metallic contact 208a, second metallic contact 208b and upper interconnect wirings 206. The upper interconnect wirings 206 may be further electrical connected to an external bonding structure (e.g., a solder bump, a micro-bump, or the like) (not shown). The first electrode layer 112a, the third electrode layer 112b, the fifth electrode layer 112c1 are electrical connected to the external bonding structure through the interconnect wirings 106, the conductive vias 108, the first metallic contact 208a and the upper interconnect wirings 206. The second electrode layer 116a, the fourth electrode layer 116b and the sixth electrode layer 116c2 are electrical connected to the external bonding structure through the second metallic contact 208b and the upper interconnect wirings 206.

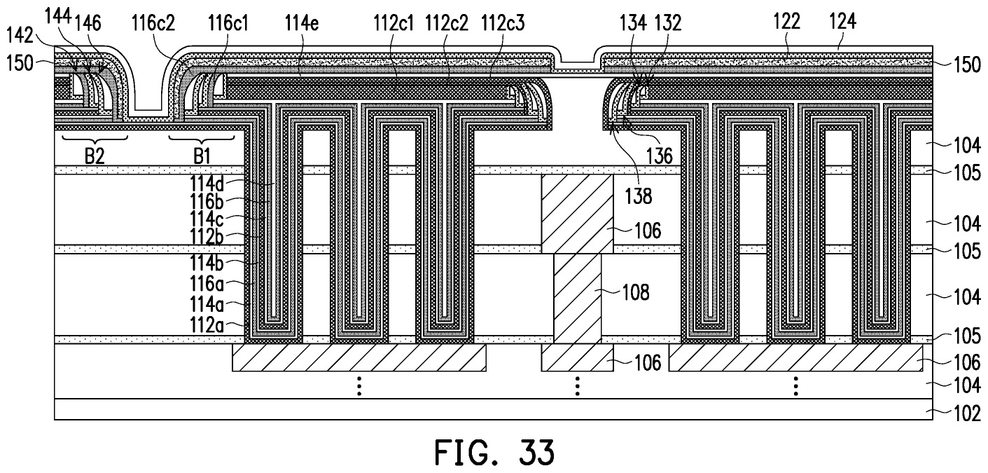

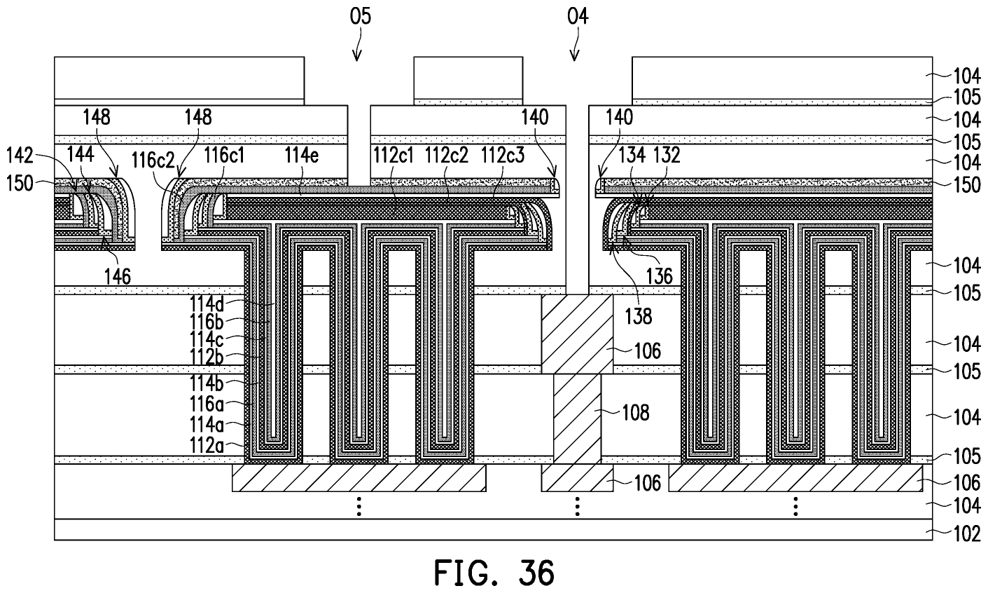

FIG. 33 to FIG. 37 illustrate the cross-sectional views of intermediate stages in the formation of a MIM device in accordance with some embodiment.

Referring FIG. 33, an insulating layer 122 is deposited on the capping layer 150 and the first dielectric layer 114a of FIG. 28. A nitride layer 124 is deposited on the insulating layer 122. In some embodiments, the insulating layer 122 and the nitride layer 124 may be formed by the same processes and the same materials as the insulating layer 122 and the nitride layer 124.

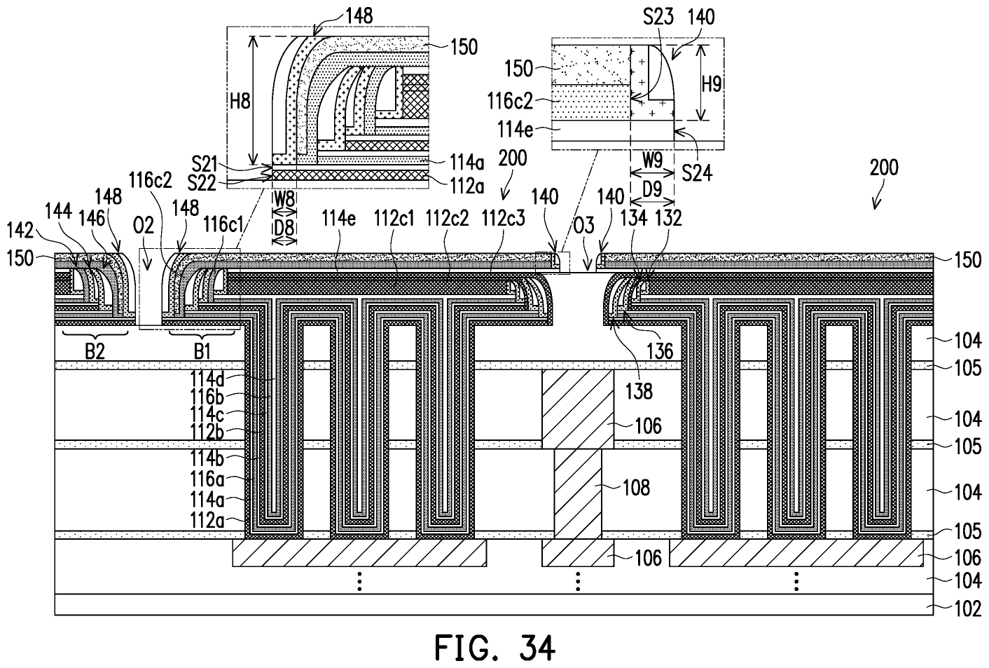

Referring FIG. 34, an eighth spacer 148 in the opening O2 may be formed by the same processes and the same materials as the first spacer 132 after depositing the insulating layer 122 and the nitride layer 124. A ninth spacer 140 in the opening O3 may be formed by the same processes and the same materials as the first spacer 132 after depositing the insulating layer 122 and the nitride layer 124. The eighth spacer 148 and a ninth spacer 140 are formed during the same process. Unless further description as follows, the processes, the materials and the effects as of forming the eighth spacer 148 and the ninth spacer 140 are the same as the first spacer 132 of FIG. 3 to FIG. 4, and will not be repeated herein.

The eighth spacer 148 is formed on a third portion of the first dielectric layer 114a to cover the capping layer 150. The ninth spacer 140 is formed on a portion of the fifth dielectric layer 114e to cover a sidewall of the capping layer 150, and a first sidewall S23 of the sixth electrode layer 116c2. Then, the first dielectric layer 114a, the first electrode layer 112a and the fifth dielectric layer 114e are patterned by using the eighth spacer 148, the ninth spacer 140 and the capping layer 150 as a mask, to reveal a second sidewall S21 of the first dielectric layer 114a, a second sidewall S22 of the first electrode layer 112a, a first sidewall S24 of the fifth dielectric layer 114e, and the insulating layer 104. Then, MIM capacitor structures 200 are formed. A single MIM capacitor structure 200 is an asymmetrical structure. The adjacent MIM capacitor structures 200 may be mirror-symmetrical to each other.

Since the first dielectric layer 114a and the first electrode layer 112a are etched according to the eighth spacer 148, the eighth spacer 148 has an outermost sidewall that is substantially aligned with the second sidewall S21 of the first dielectric layer 114a and the second sidewall S22 of the first electrode layer 112a.

Since the fifth dielectric layer 114e is etched according to the ninth spacer 140, the ninth spacer 140 has an outermost sidewall that is substantially aligned with the first sidewall S24 of the fifth dielectric layer 114e.

In some embodiments, a height H8 of the eighth spacer 148 is greater than the height H7 of the seventh spacer 146. An eighth lateral offset D8 is between the second sidewall S22 of the first electrode layer 112a and the second sidewall S20 of the second electrode layer 116a, and the eighth lateral offset D8 substantially equals to a maximum width W8 of the eighth spacer 148. In some embodiments, the eighth spacer 148 is disposed over a lateral offset region of the first electrode layer 112a.

In some embodiments, a height H9 of the ninth spacer 140 is less than the height H8 of the eighth spacer 148. A sum of the height H9 of the ninth spacer 140 and the height H4 of the fourth spacer 138 is less than the height H8 of the eighth spacer 148. A sum of the height H9 of the ninth spacer 140 and the height H7 of the seventh spacer 146 is less than the height H8 of the eighth spacer 148. A ninth lateral offset D9 is between the first sidewall S23 of the sixth electrode layer 116c2 and the first sidewall S24 of the fifth dielectric layer 114e, and the ninth lateral offset D9 substantially equals to a maximum width W9 of the ninth spacer 140. In some embodiments, the ninth spacer 140 is disposed over a lateral offset region of the fifth dielectric layer 114e.

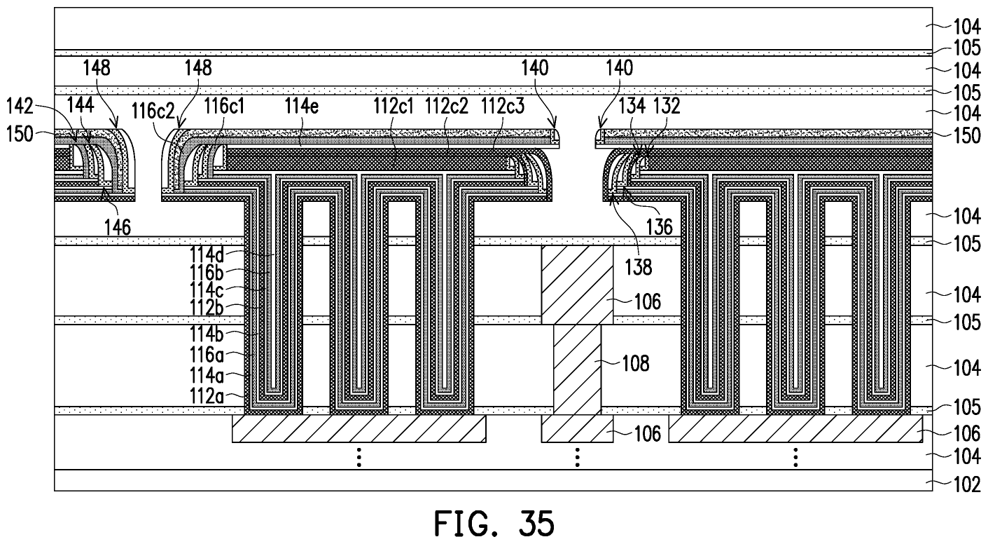

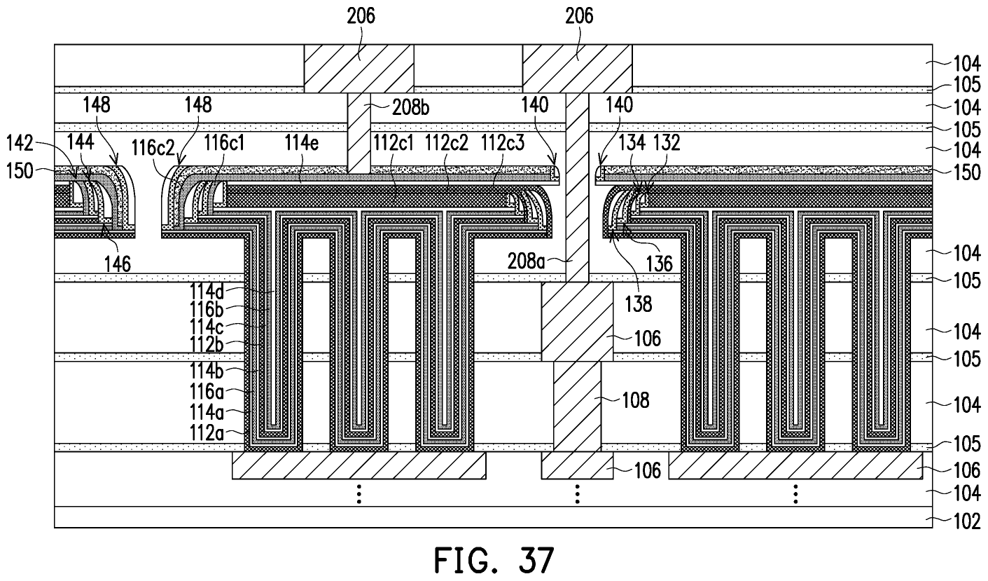

Referring FIG. 35 to FIG. 37, except for the MIM capacitor structures 200, the processes and the materials may be the same processes and the same materials as FIG. 30 to FIG. 32 and will not be repeated herein. In FIG. 37, the first metallic contact 208a, second metallic contact 208b and the upper interconnect wirings 206 are formed and may be further electrical connected to an external bonding structure (e.g., a solder bump, a micro-bump, or the like) (not shown). The first electrode layer 112a, the third electrode layer 112b, the fifth electrode layer 112c1 are electrical connected to the external bonding structure through the interconnect wirings 106, the conductive vias 108, the first metallic contact 208a and the upper interconnect wirings 206. The second electrode layer 116a, the fourth electrode layer 116b and the sixth electrode layer 116c2 are electrical connected to the external bonding structure through the second metallic contact 208b and the upper interconnect wirings 206.

A capacitor structure and a method for fabricating the capacitor are provided. The method for forming the capacitor structure including at least one pair of self-aligned spacers may decrease the number of the photomasks utilized in patterning processes of the capacitor, thereby lowering the fabrication costs of the capacitor. Accordingly, reliability and capacitance of the capacitor with the self-aligned spacers are also improved.

In accordance with some embodiments of the present disclosure, a method for fabricating a capacitor is provided. The method includes: forming a first electrode layer, a first dielectric layer covering the first electrode layer, a second electrode layer covering the first dielectric layer, a second dielectric layer covering the second electrode layer and a third electrode layer covering the second dielectric layer; patterning the third electrode layer to reveal the second dielectric layer and a first sidewall of the third electrode layer; forming a first spacer on a first portion of the second dielectric layer to cover the first sidewall of the third electrode layer; patterning the second dielectric layer and the second electrode layer by using the third electrode layer and the first spacer as a mask to reveal the first dielectric layer and a first sidewall of the second electrode layer; forming a second spacer on a first portion of the first dielectric layer to cover the first sidewall of the second electrode layer; patterning the first dielectric layer and the first electrode layer by using the third electrode layer, the first spacer and the second spacer as a mask to reveal a first sidewall of the first electrode layer; and forming a first conductive layer on the first spacer and the second spacer to electrically connect the third electrode layer and the first electrode layer. In some embodiments, the second spacer further covers a first sidewall of the second dielectric layer. In some embodiments, the first conductive layer is spaced apart from the second electrode layer by the first spacer and the second spacer. In some embodiments, the first conductive layer is in contact with a top surface of the third electrode layer and the first sidewall of the first electrode layer. In some embodiments, the method further includes: forming a first metallic contact electrically connected to an interconnect wiring; and forming a second metallic contact electrically connected to the second electrode layer. In some embodiments, the method further includes: after forming the first conductive layer, forming a third dielectric layer covering the third electrode layer; patterning the third electrode layer to reveal the second dielectric layer and a second sidewall of the third electrode layer; forming a third spacer on a second portion of the second dielectric layer to cover the second sidewall of the third electrode layer; patterning the second dielectric layer and the second electrode layer by using the third dielectric layer and the third spacer as a mask to reveal the first dielectric layer and a second sidewall of the second electrode layer; and forming a second conductive layer on the third spacer and the third dielectric layer, wherein the second conductive layer is electrically connected to the second electrode layer. In some embodiments, the method further includes: forming a trench in an insulating layer, wherein the first electrode layer, the first dielectric layer, the second electrode layer and the second dielectric layer are disposed in the trench and extend over a top surface of the insulating layer. In some embodiments, the insulating layer is formed over an interconnect wiring of an interconnect structure, and the first electrode layer lands on and is electrically connected to the interconnect wiring.

In accordance with some embodiments of the present disclosure, a capacitor structure is provided. The capacitor structure includes a first electrode layer, a first dielectric layer, a second electrode layer, a second dielectric layer, a third electrode layer, a first spacer, a second spacer, and a conductive layer. The first dielectric layer is disposed on the first electrode layer. The second electrode layer covers the first dielectric layer. The second dielectric layer covers the second electrode layer. The third electrode layer covers the second dielectric layer. The first spacer is disposed on a first portion of the second dielectric layer to cover a sidewall of the third electrode layer. The second spacer is disposed on a first portion of the first dielectric layer to cover a sidewall of the second electrode layer. The conductive layer is disposed on the first spacer and the second spacer to electrically connect the third electrode layer and the first electrode layer. In some embodiments, a thickness of the third electrode layer and substantially equals to a height of the first spacer. In some embodiments, a sum of a thickness of the second electrode layer, a thickness of the second dielectric layer and a thickness of the third electrode layer substantially equals to a height of the second spacer. In some embodiments, a height of the first spacer is less than a height of the second spacer. In some embodiments, the conductive layer is spaced apart from the second electrode layer by the first spacer and the second spacer. In some embodiments, the conductive layer is in contact with a top surface of the third electrode layer and a sidewall of the first electrode layer. In some embodiments, a first lateral offset is between the sidewall of the second electrode layer and the sidewall of the third electrode layer, and the first lateral offset substantially equals to a maximum width of the first spacer, and a second lateral offset is between the sidewall of the first electrode layer and the sidewall of the second electrode layer, and the second lateral offset substantially equals to a maximum width of the second spacer. In some embodiments, a lateral offset is between the sidewall of the second electrode layer and the sidewall of the third electrode layer, and the lateral offset substantially equals to a maximum width of the first spacer.

In accordance with some embodiments of the present disclosure, a capacitor structure is provided. The capacitor structure includes a first electrode layer, a second electrode layer, a third electrode layer, a first spacer, a second spacer, and a conductive layer. The first electrode layer, the second electrode layer and the third electrode layer are spaced apart from each other by dielectric layers. The first spacer is disposed over a first lateral offset region of the second electrode layer to cover a sidewall of the third electrode layer. The second spacer is disposed over a second lateral offset region of the first electrode layer to cover a sidewall of the second electrode layer. The conductive layer is disposed on the first spacer and the second spacer to electrically connect the third electrode layer and the first electrode layer. In some embodiments, a height of the first spacer is less than a height of the second spacer. In some embodiments, the conductive layer is in contact with a top surface of the third electrode layer and a sidewall of the first electrode layer. In some embodiments, the conductive layer is spaced apart from the second electrode layer by the first spacer and the second spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a capacitor, comprising:
forming a first electrode layer, a first dielectric layer covering the first electrode layer, a second electrode layer covering the first dielectric layer, a second dielectric layer covering the second electrode layer and a third electrode layer covering the second dielectric layer;
patterning the third electrode layer to reveal the second dielectric layer and a first sidewall of the third electrode layer;
forming a first spacer on a first portion of the second dielectric layer to cover the first sidewall of the third electrode layer;
patterning the second dielectric layer and the second electrode layer by using the third electrode layer and the first spacer as a mask to reveal the first dielectric layer and a first sidewall of the second electrode layer;
forming a second spacer on a first portion of the first dielectric layer to cover the first sidewall of the second electrode layer;
patterning the first dielectric layer and the first electrode layer by using the third electrode layer, the first spacer and the second spacer as a mask to reveal a first sidewall of the first electrode layer; and
forming a first conductive layer on the first spacer and the second spacer to electrically connect the third electrode layer and the first electrode layer.

2. The method of claim 1, wherein the second spacer further covers a first sidewall of the second dielectric layer.

3. The method of claim 1, wherein the first conductive layer is spaced apart from the second electrode layer by the first spacer and the second spacer.

4. The method of claim 1, wherein the first conductive layer is in contact with a top surface of the third electrode layer and the first sidewall of the first electrode layer.

5. The method of claim 1 further comprising:
forming a first metallic contact electrically connected to an interconnect wiring; and
forming a second metallic contact electrically connected to the second electrode layer.

6. The method of claim 1 further comprising:
after forming the first conductive layer, forming a third dielectric layer covering the third electrode layer;
patterning the third electrode layer to reveal the second dielectric layer and a second sidewall of the third electrode layer;
forming a third spacer on a second portion of the second dielectric layer to cover the second sidewall of the third electrode layer;
patterning the second dielectric layer and the second electrode layer by using the third dielectric layer and the third spacer as a mask to reveal the first dielectric layer and a second sidewall of the second electrode layer; and
forming a second conductive layer on the third spacer and the third dielectric layer, wherein the second conductive layer is electrically connected to the second electrode layer.

7. The method of claim 1 further comprising:
forming a trench in an insulating layer, wherein the first electrode layer, the first dielectric layer, the second electrode layer and the second dielectric layer are disposed in the trench and extend over a top surface of the insulating layer.

8. The method of claim 7, wherein the insulating layer is formed over an interconnect wiring of an interconnect structure, and the first electrode layer lands on and is electrically connected to the interconnect wiring.

9. A capacitor structure, comprising:
a first electrode layer;
a first dielectric layer disposed on the first electrode layer;
a second electrode layer covering the first dielectric layer;
a second dielectric layer covering the second electrode layer;
a third electrode layer covering the second dielectric layer;
a first spacer disposed on a first portion of the second dielectric layer to cover a sidewall of the third electrode layer;
a second spacer disposed on a first portion of the first dielectric layer to cover a sidewall of the second electrode layer; and
a conductive layer disposed on the first spacer and the second spacer to electrically connect the third electrode layer and the first electrode layer.

10. The capacitor structure of claim 9, wherein a thickness of the third electrode layer and substantially equals to a height of the first spacer.

11. The capacitor structure of claim 9, wherein a sum of a thickness of the second electrode layer, a thickness of the second dielectric layer and a thickness of the third electrode layer substantially equals to a height of the second spacer.

12. The capacitor structure of claim 9, wherein a height of the first spacer is less than a height of the second spacer.

13. The capacitor structure of claim 9, wherein the conductive layer is spaced apart from the second electrode layer by the first spacer and the second spacer.

14. The capacitor structure of claim 9, wherein the conductive layer is in contact with a top surface of the third electrode layer and a sidewall of the first electrode layer.

15. The capacitor structure of claim 14, wherein
a first lateral offset is between the sidewall of the second electrode layer and the sidewall of the third electrode layer, and the first lateral offset substantially equals to a maximum width of the first spacer, and
a second lateral offset is between the sidewall of the first electrode layer and the sidewall of the second electrode layer, and the second lateral offset substantially equals to a maximum width of the second spacer.

16. The capacitor structure of claim 9, wherein a lateral offset is between the sidewall of the second electrode layer and the sidewall of the third electrode layer, and the lateral offset substantially equals to a maximum width of the first spacer.

17. A capacitor structure, comprising:
a first electrode layer;
a second electrode layer;
a third electrode layer, wherein the first electrode layer, the second electrode layer and the third electrode layer are spaced apart from each other by dielectric layers;
a first spacer disposed over a first lateral offset region of the second electrode layer to cover a sidewall of the third electrode layer;
a second spacer disposed over a second lateral offset region of the first electrode layer to cover a sidewall of the second electrode layer; and
a conductive layer disposed on the first spacer and the second spacer to electrically connect the third electrode layer and the first electrode layer.

18. The capacitor structure of claim 17, wherein a height of the first spacer is less than a height of the second spacer.

19. The capacitor structure of claim 17, wherein the conductive layer is in contact with a top surface of the third electrode layer and a sidewall of the first electrode layer.

20. The capacitor structure of claim 17, wherein the conductive layer is spaced apart from the second electrode layer by the first spacer and the second spacer.
